(19) United States
(12) Patent Application Publication
(10) Pub. No.: US 2026/0129835 A1
(43) Pub. Date: May 7, 2026

(54) SEMICONDUCTOR DEDVICE AND METHOD FOR FABRICATING THE SAME

(71) Applicant: SK hynix Inc., Gyeonggi-do (KR)

(72) Inventors: Yeon Gyu LEE, Gyeonggi-do (KR); Min Chul SUNG, Gyeonggi-do (KR); Seung Wook RYU, Gyeonggi-do (KR)

(21) Appl. No.: 19/362,500

(22) Filed: Oct. 20, 2025

(30) Foreign Application Priority Data
Nov. 6, 2024 (KR) 10-2024-0156248

(51) Int. Cl. H10B 12/00; H01L 23/528; H10D 30/01; H10D 30/60

(52) U.S. Cl. CPC H10B 12/315; H10B 12/482; H10D 30/611; H10D 30/023; H10W 20/435

(57) ABSTRACT

Disclosed is a semiconductor device which includes a first gate that extends in a first direction, an island gate adjacent to one end of the first gate in the first direction, a second gate that is spaced apart from the first gate in a second direction perpendicular to the first direction and that extends in the first direction, and a contact plug in contact with the island gate and the second gate.

### CROSS-REFERENCE TO RELATED APPLICATION

This application claims the benefit of priority to Korean Patent Application No. 10-2024-0156248, filed on Nov. 6, 2024, the entire contents of which are incorporated herein by reference.

### TECHNICAL FIELD

The embodiments of the present disclosure relate generally to a semiconductor device, and more particularly, relates to a semiconductor device including a memory cell.

### BACKGROUND

As compactness of semiconductor devices and an improvement in the degree of integration thereof are emerging as a major issue, memory cells included in the semiconductor devices may be formed to have a three-dimensional pattern, and the operating characteristics of the memory cells may be improved.

As semiconductor devices become more compact and highly integrated, memory cells within them are increasingly designed with three-dimensional structures. This 3D configuration enhances the operating performance of memory cells, helping overcome limitations of traditional 2D layouts and supporting the advancement of modern chip technology. Since these 3D structures are relatively new, ongoing research is focused on improving their structural integrity, reliability, and overall performance characteristics.

### SUMMARY

The embodiments of the present disclosure have been made to solve issues occurring in the prior art while advantages achieved by the prior art are maintained intact.

According to embodiments of the present disclosure, a three-dimensional semiconductor device is provided (hereinafter simply referred to as semiconductor device) which exhibits, among other improvements, improved integration.

The semiconductor device according to an embodiment may include an island gate to improve contact stability between a gate and a contact plug included in the semiconductor device.

In addition, the semiconductor device of the present disclosure may include an island gate connected to the contact plug for securing a margin for the formation of the contact plug and for reducing the difficulty level of the process.

It is noted that the technical problems solved by the embodiments of the present disclosure are not limited to the aforementioned problems, and other technical problems not mentioned herein will be clearly understood from the following description by those having ordinary skill in the art to which the present disclosure pertains.

According to an embodiment of the present disclosure, a semiconductor device includes a first gate that extends in a first direction, an island gate adjacent to one end of the first gate in the first direction, a second gate that is spaced apart from the first gate in a second direction perpendicular to the first direction and that extends in the first direction, and a contact plug in contact with the island gate and the second gate.

According to an embodiment, the island gate may have a quadrangular shape, and the second gate may surround at least three sides of the island gate.

According to an embodiment, the second gate may include a bridge portion disposed between the island gate and the first gate.

According to an embodiment, the second gate may contact the island gate.

According to an embodiment, the semiconductor device may further include a bit line that is spaced apart from the first gate in a third direction perpendicular to the first direction and the second direction and that extends in the second direction.

According to an embodiment, the semiconductor device may further include an active region in contact with the bit line, and the active region may include a horizontal portion that is in contact with the bit line and extends in the second direction and a vertical portion that extends in the third direction.

According to an embodiment, the vertical portion may be disposed between the first gate and the second gate.

According to an embodiment, the first gate may be disposed between the vertical portions included in the adjacent active regions, respectively.

According to an embodiment, the active region may include an oxide semiconductor.

According to an embodiment, the semiconductor device may further include a separation region that separates adjacent second gates from each other.

According to an embodiment, the separation region may be disposed between the first gate and the island gate.

According to an embodiment, the separation region may contact one end of the second gate in the first direction.

According to an embodiment, a voltage provided to the first gate may be different from a voltage provided to the second gate.

According to an embodiment, the voltage provided to the first gate may be a ground voltage.

According to an embodiment, the semiconductor device may further include another island gate adjacent to an opposite end of the first gate in the first direction and another contact plug electrically connected to the another island gate.

According to an embodiment, the contact plug and the other contact plug may be disposed in a diagonal direction with respect to the center of the first gate.

According to another embodiment of the present disclosure, a semiconductor device includes a first gate that extends in a first direction, a bit line that extends in a second direction perpendicular to the first direction, a second gate spaced apart from the first gate in the second direction, an active region including a horizontal portion in contact with the bit line and a vertical portion that extends in a third direction perpendicular to the first direction and the second direction, an island gate adjacent to one end of the first gate in the first direction, and a contact plug that overlaps the island gate and the second gate, and the vertical portion is disposed between the first gate and the second gate.

According to an embodiment, the semiconductor device may further include a separation region that separates adjacent second gates from each other.

According to another embodiment of the present disclosure, a semiconductor device includes a first gate and a second gate extending in a first direction and spaced apart from each other in a second direction that is perpendicular to the first direction, and an island gate adjacent to a first end of the first gate. The second gate surrounds three sides of the island gate, and the second gate includes a bridge portion disposed between the island gate and the first gate.

### BRIEF DESCRIPTION OF THE DRAWINGS

The above and other objects, features and advantages of the embodiments of the present disclosure will become more apparent from the following detailed description taken in conjunction with the accompanying drawings wherein:

FIG. 1 is a schematic perspective view of a semiconductor device according to an embodiment of the present disclosure;

FIG. 2A is a sectional view of the semiconductor device according to an embodiment of the present disclosure;

FIG. 2B is a sectional view of the semiconductor device according to an embodiment of the present disclosure;

FIG. 2C is a sectional view of the semiconductor device according to an embodiment of the present disclosure;

FIG. 2D is a sectional view of the semiconductor device taken along cutting line X1-X1′ of FIG. 2A;

FIG. 2E is a sectional view of the semiconductor device taken along cutting line X2-X2′ of FIG. 2B;

FIG. 2F is a sectional view of the semiconductor device taken along cutting line X3-X3′ of FIG. 2C;

FIGS. 3A to 16A are perspective views for describing fabrication operations of the semiconductor device according to an embodiment of the present disclosure;

FIGS. 3B to 16B are sectional views in one direction for describing the fabrication operations of the semiconductor device according to an embodiment of the present disclosure;

FIGS. 3C to 15C are sectional views in another direction for describing the fabrication operations of the semiconductor device according to an embodiment of the present disclosure;

FIG. 17 is a schematic perspective view of a semiconductor device according to an embodiment of the present disclosure;

FIG. 18A is a sectional view of the semiconductor device according to an embodiment of the present disclosure;

FIG. 18B is a sectional view of the semiconductor device according to an embodiment of the present disclosure;

FIG. 18C is a sectional view of the semiconductor device taken along cutting line X4-X4′ of FIG. 18A;

FIG. 18D is a sectional view of the semiconductor device taken along cutting line X5-X5′ of FIG. 18B;

FIGS. 19A to 31A are perspective views for describing fabrication operations of the semiconductor device according to an embodiment of the present disclosure;

FIGS. 19B to 31B are sectional views in one direction for describing the fabrication operations of the semiconductor device according to an embodiment of the present disclosure;

FIGS. 19C to 31C are sectional views in another direction for describing the fabrication operations of the semiconductor device according to an embodiment of the present disclosure; and

FIG. 32 is a sectional perspective view of the semiconductor device according to an embodiment of the present disclosure.

### DETAILED DESCRIPTION

Hereinafter, various embodiments of the present disclosure will be described with reference to the accompanying drawings. The above and other aspects, features, and advantages of the embodiments of the present disclosure will become apparent from the following description of embodiments given in conjunction with the accompanying drawings. However, this is not intended to limit the embodiments of the present disclosure to particular embodiments.

The embodiments of the present disclosure are not limited to the embodiments disclosed herein and may be implemented in various different forms. Those skilled in the art to which the present disclosure pertains will recognize that modifications, equivalents, and/or alternatives of the various embodiments described herein can be variously made without departing from the scope and technical concepts of the present disclosure.

In adding the reference numerals to the components of each drawing, it should be noted that identical components may be designated by the identical reference numerals even when they are displayed on other drawings.

In describing the embodiments of the present disclosure, a detailed description of well-known features or functions may be omitted to not unnecessarily obscure the description of the features of the embodiments.

As used herein, singular forms may include plural forms as well, unless the text clearly indicates otherwise. It will be further understood that the terms “comprise” and/or “comprising”, when used in this specification, specify the presence of stated components, steps, operations, and/or elements, but do not preclude the presence or addition of one or more other components, steps, operations, and/or elements.

Hereinafter, semiconductor devices and methods for fabricating the same according to embodiments of the present disclosure will be described with reference to the accompanying drawings.

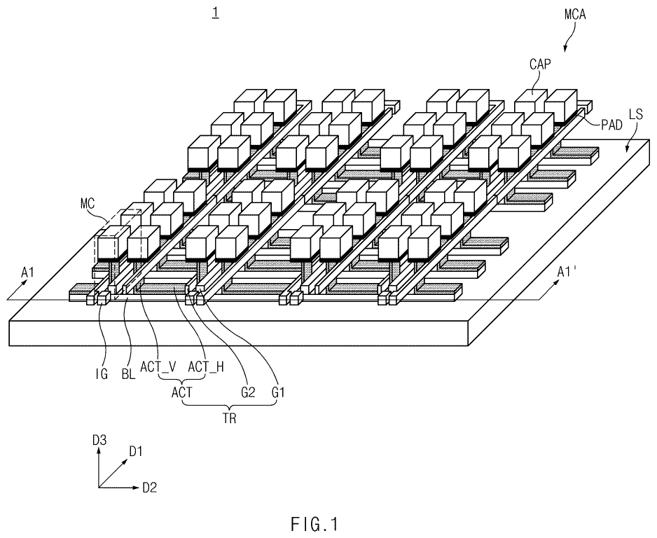

FIG. 1 is a schematic perspective view of a semiconductor device 1 according to an embodiment of the present disclosure.

The structure of the semiconductor device 1 will be described with reference to FIG. 1.

The semiconductor device 1 may include a substrate LS and a plurality of memory cells formed on the substrate LS and repeatedly arranged. Each of the memory cells may have a three-dimensional structure.

Referring to FIG. 1, the semiconductor device 1 may include the substrate LS, and a memory cell array MCA formed on the substrate LS. The memory cell array MCA may include a plurality of memory cells MC repeatedly arranged on the substrate LS.

According to an embodiment, each of the memory cells MC may have a three-dimensional structure.

For example, each of the memory cells MC included in the memory cell array MCA may include a bit line BL, a transistor TR, a contact pad PAD, a capacitor CAP, and an island gate IG.

The bit line BL may be disposed on the substrate LS and may extend in a second direction D2 parallel to one surface of the substrate LS. Adjacent bit lines BL may be separated from each other by an insulating layer (not illustrated).

The insulating layer may include, for example, silicon oxide, silicon nitride, metal oxide, metal oxy nitride, metal silicate, a high-k material, a ferroelectric material, an anti-ferroelectric material, or a combination thereof. In an embodiment, the insulating layer may include silicon dioxide (SiO₂), silicon nitride (Si₃N₄), hafnium oxide (HfO₂), aluminum oxide (Al₂O₃), zirconium oxide (ZrO₂), aluminum oxynitride (AlON), hafnium oxynitride (HfON), hafnium silicate (HfSiO), hafnium silicon oxynitride (HfSiON), and silicon carbide oxide (SiCO)

According to an embodiment, the capacitor CAP may be spaced apart from the bit line BL in a third direction D3 and may be arranged in a matrix form.

According to an embodiment, the capacitor CAP may be obliquely arranged with respect to the region where gates G1 and G2 overlap with the bit line BL. For example, the capacitor CAP may be disposed not to be aligned with the center of the contact pad PAD in contact with one side of an active region ACT and may be arranged in a zig-zag shape or a honeycomb shape with respect to the contact pads PAD arranged in a matrix form.

The transistor TR may be disposed between the capacitor CAP and the bit line BL in the third direction D3.

The transistor TR may include at least a portion of the active region ACT connected with the bit line BL and may include the first gate G1 and the second gate G2.

According to an embodiment, a word line driving voltage may be provided to the second gate G2 extending in a first direction D1. The second gate G2 may operate as a word line of the transistor TR.

In this case, the first gate G1 which extends to face the second gate G2 may operate to block interference between the gates G2 of adjacent transistors TR.

For example, a voltage provided to the first gate G1 may be different from a voltage provided to the second gate G2.

A ground voltage may be provided to the first gate G1, and the word line driving voltage may be provided to the second gate G2. The first gate G1, to which the ground voltage is provided, may operate as a back gate.

The first direction D1 may be a direction perpendicular to the second direction D2, and the third direction D3 may be a direction perpendicular to the first direction D1 and the second direction D2.

Each of the memory cells MC may include the contact pad PAD electrically connecting the capacitor CAP and the bit line BL. The contact pad PAD may contact one end of a vertical portion included in the active region ACT.

The active region ACT may include a channel region and source/drain regions of the transistor TR. For example, depending on the voltage applied to the second gate G2 of the transistor TR, the channel region may be formed in the active region ACT, and electrons may move between the source/drain regions through the formed channel region.

The active region ACT may include a horizontal portion ACT_H extending in the second direction D2 and the vertical portions ACT_V extending in the third direction D3.

Each of the memory cells MC may include one transistor TR.

Two adjacent vertical portions ACT_V included in each active region ACT may be connected by one horizontal portion ACT_H. The horizontal portion ACT_H of the active region ACT may be connected with the bit line BL. In addition, the active region ACT may be electrically isolated from the gates G1 and G2 by an insulating layer.

An insulating material included in the insulating layer may include, for example, silicon oxide, silicon nitride, metal oxide, metal oxy nitride, metal silicate, a high-k material, a ferroelectric material, an anti-ferroelectric material, or a combination thereof.

The memory cell array MCA may include a DRAM memory cell array. In an embodiment, the memory cell array MCA may include PCRAM, PERAM, or MRAM, and the capacitor CAP may be replaced with a different memory element.

The substrate LS may include a material suitable for semiconductor processing. The substrate LS may include at least one of a conductive material, a dielectric material, or a semiconductor material.

The substrate LS may include a semiconductor substrate. The substrate LS may be formed of a semiconductor material containing silicon. The substrate LS may include silicon, single crystal silicon, poly silicon, amorphous silicon, silicon germanium, single crystal silicon germanium, polycrystalline silicon germanium, carbon doped silicon, a combination thereof, or multiple layers thereof. The substrate LS may include a different semiconductor material such as germanium. The substrate LS may include a group III/V semiconductor substrate, for example, a compound semiconductor substrate such as gallium arsenide (GaAs).

The substrate LS may include a silicon on insulator (SOI) substrate. In an embodiment, the substrate LS may include a peripheral circuit region (not illustrated) in the lower portion thereof. The peripheral circuit region may include a plurality of control circuits for controlling the memory cell array MCA. In an embodiment, at least one control circuit of the peripheral circuit region may include an N-channel transistor, a P-channel transistor, a CMOS circuit, or a combination thereof. At least one control circuit of the peripheral circuit region may include an address decoder circuit, a read circuit, and a write circuit.

In an embodiment, at least one control circuit included in the peripheral circuit region may include a planar channel transistor, a recess channel transistor, a buried gate transistor, or a fin channel transistor (FinFET).

In an embodiment, at least one control circuit included in the peripheral circuit region may be electrically connected to the bit line BL. The peripheral circuit region may include a sense amplifier, and the sense amplifier may be electrically connected to the bit line BL. Although not illustrated, a multi-level metal interconnection may be disposed between the memory cell array MCA and the substrate LS, and the peripheral circuit region and the bit line BL may be connected with each other through the multi-level metal interconnection MLM.

The bit line BL may be disposed over the substrate LS and may be laterally oriented in the second direction D2, and an insulating layer may be disposed between the bit lines BL.

The bit line BL may be referred to as a laterally-oriented bit line or a laterally-extended bit line.

The bit line BL may include a conductive material. The bit line BL may include a silicon-base material, a metal-base material, or a combination thereof. The bit line BL may include poly silicon, metal, metal nitride, metal silicide, or a combination thereof.

The bit line BL may include poly silicon, titanium nitride, tungsten (W), or a combination thereof. For example, the bit line BL may include poly silicon or titanium nitride (TiN) doped with an N-type impurity.

The bit line BL may include a stack TiN/W of titanium nitride and tungsten. The bit line BL may further include an ohmic contact such as metal silicide. According to an embodiment, the bit line BL may be formed of a single layer including a metal nitride layer or a metal layer.

The memory cells MC laterally arranged in the second direction D2 may share one bit line BL. An insulating layer extending in the second direction D2 may be provided between adjacent bit lines BL. For example, the insulating layer may be constituted by a plurality of layers and may function as a spacer that spaces the adjacent bit lines BL apart from each other. In an embodiment, the insulating layer may include silicon nitride or silicon oxide.

The transistors TR may be arranged in a matrix form in the first direction D1 and the second direction D2.

The transistor TR may be disposed between the bit line BL and the capacitor CAP.

The transistor TR may include the active region ACT, an insulating layer (not illustrated), and the gates G1 and G2.

The gates G1 and G2 may extend in the first direction D1. The active region ACT may include the horizontal portion ACT_H extending in the second direction D2 and the vertical portion ACT_V extending in the third direction D3.

The insulating layer may be disposed to separate the active region ACT and the gates G1 and G2 from each other.

The gates G1 and G2 may include a metal, a metal mixture, a metal alloy, titanium nitride, tungsten, poly silicon, or a combination thereof.

For example, the gates G1 and G2 may include a stack TiN/W in which titanium nitride and tungsten are sequentially stacked.

The gates G1 and G2 and the bit line BL may extend in directions crossing each other. The active region ACT may include a semiconductor material or an oxide semiconductor material.

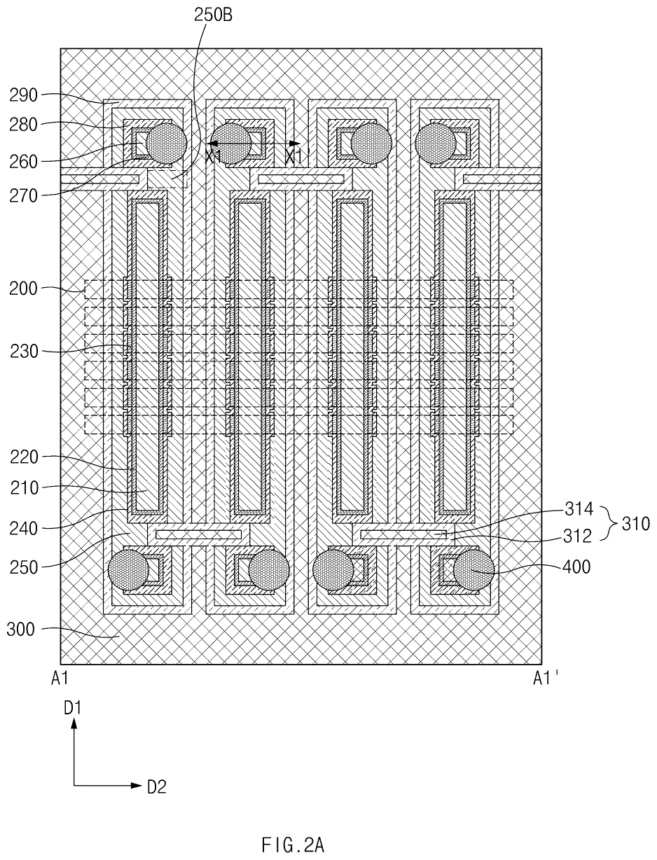

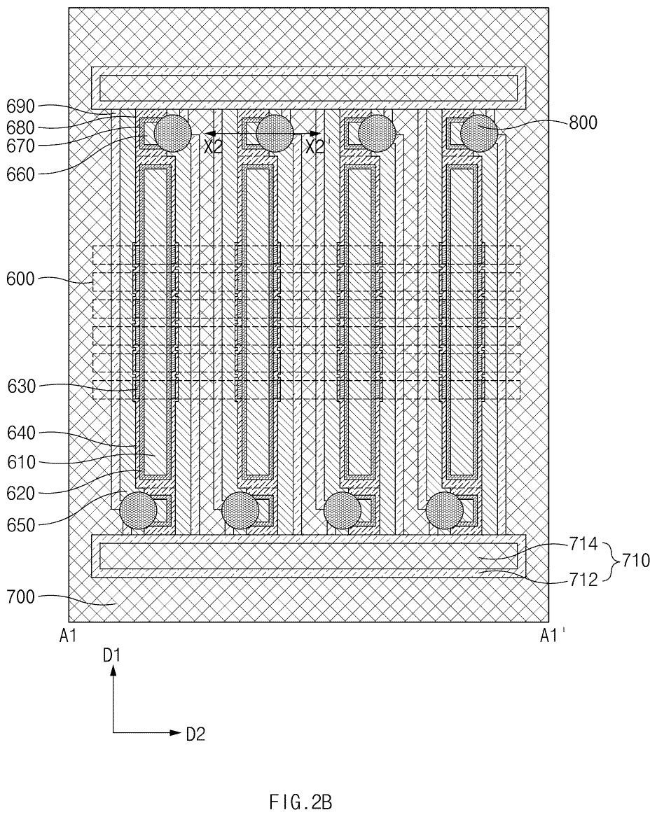

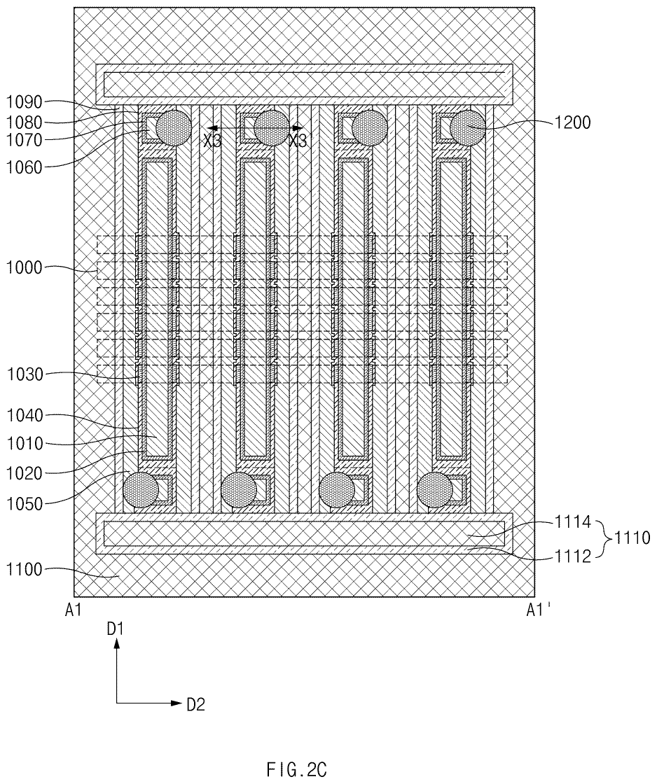

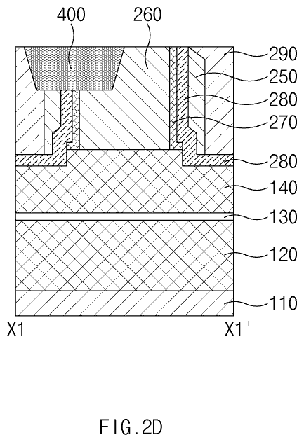

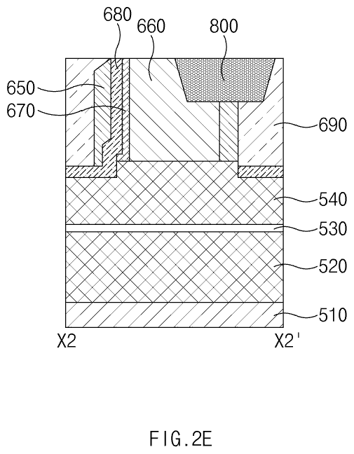

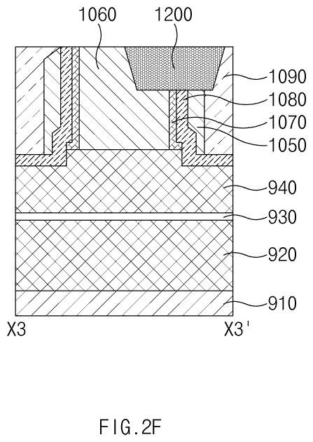

The island gates IG may be disposed at opposite ends of the gate G1 extending in the first direction D1. Each of the island gates IG may be electrically connected with one second gate G2. The specific shape and function of the island gate IG and the connection relationship between the island gate IG and the second gate G2 will be described in detail with reference to FIGS. 2A to 2C. The island gate IG may include the same conductive material as the gates G1 and G2.

The bit line BL may be electrically isolated from the gates G1 and G2 by an insulating layer. For example, the insulating layer may be disposed between the bit line BL and the gates G1 and G2.

The active region ACT may include a plurality of impurity regions. The impurity regions may include the source/drain regions of the transistor TR.

For example, the active region ACT may include doped poly silicon, undoped poly silicon, amorphous silicon, indium gallium zinc oxygen (IGZO) semiconductor, indium zinc oxide (IZO), indium tin oxide (ITO), and indium oxide (InO₃).

The horizontal portion ACT_H included in the active region ACT may be electrically connected with the bit line BL. In addition, the contact pad PAD may contact the vertical portion ACT_V included in the active region ACT, and the capacitor CAP and the active region ACT may be electrically connected through the contact pad PAD.

A gate insulating layer may be disposed between the active region ACT and the gates G1 and G2. The gate insulating layer may prevent electrical connection between the active region ACT and the gates G1 and G2.

The gate insulating layer may include, for example, silicon oxide, silicon nitride, metal oxide, metal oxy nitride, metal silicate, a high-k material, a ferroelectric material, an anti-ferroelectric material, or a combination thereof.

In addition, a gate spacer may be disposed between the gates G1 and G2 for electrically isolating the gates G1 and G2 from each other.

An insulating layer may include, for example, silicon oxide, hafnium oxide, zirconium oxide, or aluminum oxide. The insulating layer may have different compositions depending on its location. For example, the insulating layer disposed between the gates G1 and G2 may include silicon oxide, and the insulating layer disposed between the gates G1 and G2 and the active region ACT may include a high-k material.

The capacitor CAP may have a shape vertically extending in the third direction and may be disposed in contact with the vertical portion ACT_V included in the active region ACT. The capacitor CAP may include a metal-insulator-metal (MIM) structure.

The capacitor CAP may include an upper electrode, a lower electrode, and a dielectric layer disposed between the two electrodes. The dielectric layer may include silicon oxide, silicon nitride, a high-k material, or a combination thereof.

The high-k material may have a higher dielectric constant than silicon oxide. The silicon oxide (SiO₂) may have a dielectric constant of about 3.9, and the dielectric layer may include a high-k material having a dielectric constant of 4 or more. For example, the high-k material may have a dielectric constant of about 20 or more.

The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In an embodiment, the dielectric layer may be formed of a composite layer including two or more layers of the high-k material mentioned above.

The dielectric layer may include a stack of a high-k material and a high band gap material having a band gap greater than that of the high-k material. For example, the dielectric layer may include silicon oxide (SiO₂) as another high band gap material, in addition to aluminum oxide (Al₂O₃). Since the dielectric layer includes the high band gap material, leakage current may be suppressed.

The dielectric layer may include a laminated structure in which a high-k material and a high band gap material are alternately stacked. For example, the dielectric layer may include a ZAZA (ZrO₂/Al₂O₃/ZrO₂/Al₂O₃), ZAZAZ (ZrO₂/Al₂O₃/ZrO₂/Al₂O₃/ZrO₂), HAHA (HfO₂/Al₂O₃/HfO₂/Al₂O₃), or HAHAH (HfO₂/Al₂O₃/HfO₂/Al₂O₃/HfO₂) stack structure.

The upper electrode and the lower electrode included in the capacitor CAP may include metal, noble metal, metal nitride, conductive metal oxide, conductive noble metal oxide, metal carbide, metal silicide, or a combination thereof. For example, the upper and lower electrodes included in the capacitor CAP may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, or a tungsten nitride/tungsten (WN/W) stack.

According to an embodiment, the electrodes included in the capacitor CAP may include a combination of a metal-base material and a silicon-base material. For example, the electrodes included in the capacitor CAP may include a stack of titanium nitride/silicon germanium/tungsten nitride (TiN/SiGe/WN).

The capacitor CAP may have a three-dimensional structure. The capacitor CAP having the three-dimensional structure may be repeatedly disposed in a matrix form with respect to one surface of the substrate LS. The three-dimensional structure may be, for example, a cylinder shape, a pillar shape, or a pylinder shape. Here, the pylinder shape may refer to a structure in which a pillar shape and a cylinder shape are merged.

According to an embodiment, the capacitor CAP may have a structure obliquely arranged with respect to the contact pad PAD disposed in the region where the bit line BL and the gates G1 and G2 overlap, such that the largest number of capacitors are disposed in the same area.

Each of the memory cells MC may share the first gate G1 and the second gate G2. The first gate G1 and the second gate G2 may include the same conductive material.

The control circuits included in the peripheral circuit region may be connected with the first gate G1, the second gate G2, or the bit line BL through a contact plug.

The contact plug may be a vertical via extending from a conductive line included in the control circuits to the first gate G1, the second gate G2, or the bit line BL. The contact plug may include a conductive material such as metal or silicon, and a control signal may be provided to the first gate G1, the second gate G2, or the bit line BL through the contact plug.

FIG. 2A is a sectional view of the semiconductor device according to an embodiment of the present disclosure. FIG. 2B is a sectional view of the semiconductor device according to an embodiment of the present disclosure. FIG. 2C is a sectional view of the semiconductor device according to an embodiment of the present disclosure.

In FIGS. 2A, 2B, and 2C, the semiconductor device is illustrated as including six bit lines 200, 600, or 1000, four first gates 210, 610, or 1010, and eight second gates 250, 650, or 1050. However, this is merely illustrative, and the semiconductor device may actually include more bit lines and gates. In addition, the cross-sections illustrated in FIGS. 2A, 2B, and 2C may be exaggerated or modified for convenience of description.

Each of FIGS. 2A, 2B, and 2C is a sectional view of the semiconductor device 1 taken along line A1-A1′ of FIG. 1. Line A1-A1′ may be a line that cuts at least portions of the first gates 210, 610, or 1010, the second gates 250, 650, or 1050, and island gates 260, 660, or 1060 so as to disclose the positional relationship between the first gates 210, 610, or 1010, the second gates 250, 650, or 1050, and the island gates 260, 660 or 1060.

In FIG. 2A, the bit line 200 disposed in the substrate is illustrated by a dotted line. The bit line 200 may be disposed to overlap with the first gate 210, the second gate 250, and an active region 230. The bit line 200 may extend in the second direction D2 and may include a conductive material.

The conductive material included in the bit line 200 may include, for example, poly silicon, metal, metal nitride, metal silicide, or a combination thereof.

For example, the bit line 200 may include poly silicon, titanium nitride, tungsten, or a combination thereof. In addition, in an embodiment, the bit line 200 may include a stack TiN/W of titanium nitride and tungsten or a stack TiN/W/TiN of titanium nitride, tungsten, and titanium nitride.

The first gate 210 may be disposed over the bit line 200. The first gate 210 may extend in the first direction D1 and may include a conductive material. The first gate 210 may include, for example, a metal-base material, a semiconductor material, or a combination thereof. For example, the first gate 210 may include a single titanium nitride film.

According to an embodiment, a voltage provided to the first gate 210 may be a ground voltage. Providing the ground voltage to the first gate 210 allows blocking any interference between the second gates 250. The first gate 210 may operate as a back gate.

A first gate insulating layer 220 may be formed between the first gate 210 and the active region 230 and may surround the first gate 210. The first gate insulating layer 220 may include an insulating material, such as, for example, silicon oxide, silicon nitride, metal oxide, metal oxy nitride, metal silicate, a high-k material, a ferroelectric material, an anti-ferroelectric material, or a combination thereof. The first gate insulating layer 220 may include SiO₂, Si₃N₄, HfO₂, Al₂O₃, ZrO₂, AlON, HfON, HfSiO, HfSiON, or a combination thereof.

The active region 230 may include a vertical portion extending in the third direction (the direction D3 of FIG. 1) along the sidewall of the first gate 210. The active region 230 illustrated in FIG. 2A may correspond to the planar shape (top surface) of the vertical portion ACT_V included in the active region ACT illustrated in FIG. 1.

The active region 230 may include, for example, an oxide semiconductor material, and the oxide semiconductor material may include indium gallium zinc oxide (IGZO).

According to an embodiment, the active region 230 may include doped poly silicon, undoped poly silicon, single crystal silicon, germanium, silicon-germanium amorphous silicon, indium zinc oxide (IZO), indium tin oxide (ITO), and indium oxide (InO₃).

Since IGZO has low leakage current characteristics, the semiconductor device having low standby power may be implemented by forming the active region 230 with IGZO. In addition, since the active region 230 includes IGZO, the difficulty level of a process may be lowered, and the active region 230 having a three-dimensional structure that includes a vertical portion and a horizontal portion may be easily formed.

A second gate insulating layer 240 may be disposed between the second gate 250 and the active region 230 and may be formed outside the first gate insulating layer 220 to surround the first gate 210. The second gate insulating layer 240 may include an insulating material, such as, for example, silicon oxide, silicon nitride, metal oxide, metal oxy nitride, metal silicate, a high-k material, a ferroelectric material, an anti-ferroelectric material, or a combination thereof. The second gate insulating layer 240 may include SiO₂, Si₃N₄, HfO₂, Al₂O₃, ZrO₂, AlON, HfON, HfSiO, HfSiON, or a combination thereof.

The second gate 250 may include a structure extending in the first direction D1 and may be disposed along the sidewall of the first gate 210. In addition, one side of the second gate 250 that is adjacent to the island gate 260 may be disposed to surround the island gate 260.

The second gate 250 may be spaced apart from the first gate 210 in the second direction D2.

The second gate 250 may include a bridge portion 250B disposed between the island gate 260 and the first gate 210.

The bridge portion 250B may be a region protruding in the second direction D2 perpendicular to the first direction D1 in which the second gate 250 extends.

The second gate 250 may include a conductive material, such as, for example, a metal-base material, a semiconductor material, or a combination thereof. For example, the second gate 250 may include a single titanium nitride film.

The island gates 260 may be disposed at the opposite ends of the first gate 210 extending in the first direction (e.g., the direction D1). The island gate 260 may be electrically isolated from the first gate 210 and the second gate 250 by a first island gate insulating layer 270 and a second island gate insulating layer 280.

Since the island gates 260 are spaced apart from the opposite ends of the first gate 210 by a preset distance, separation between a contact plug 400 in contact with the island gate 260 and the first gate 210 may be facilitated.

In addition, since the island gate 260 and the first gate 210 are spaced apart from each other, a margin for separating the second gates 250 may be secured.

The island gate 260 may include the same conductive material as the first gate 210 or the second gate 250. The island gate 260 may be in a floating state before being connected with the contact plug 400 and may be electrically connected with the second gate 250 by the contact plug 400.

According to an embodiment, the cross-section of the island gate 260 may have a quadrangular shape. In the second direction, the width(length) of the island gate 260 may be the same as the width of the first gate 210.

One side of the second gate 250 may be formed to surround at least three sides of the island gate 260. Since the one side of the second gate 250 is formed to surround at least three sides of the island gate 260, the contact area between the contact plug 400, the island gate 260, and the second gate 250 may be easily secured when the contact plug 400 is formed.

Since a margin for forming the contact plug 400 is secured, the difficulty level of the manufacturing process may be lowered, and poor contact between the contact plug 400 and the second gate 250 may be prevented.

A gate spacer 290 may electrically isolate adjacent second gates 250 from each other. The gate spacer 290 may include, for example, silicon nitride.

A second interlayer insulating layer 300 may surround the gate spacer 290. The second interlayer insulating layer 300 may include silicon oxide and may separate adjacent gate spacers 290 from each other.

A separation region 310 may electrically isolate two second gates 250 adjacent to the opposite sides of the first gate 210 with any first gate 210 therebetween. Each of the second gates 250 which are separated by the separation region 310 may operate as a word line.

The separation region 310 may be disposed between adjacent second gates 250 and may electrically isolate the second gates 250 located on the sidewall of one first gate 210.

Different word line control signals may be provided to the second gates 250 separated by the separation region 310.

The separation region 310 may include a first separation layer 312 and a second separation layer 314. For example, the first separation layer 312 may include silicon nitride, and the second separation layer 314 may include silicon oxide.

The separation region 310 may be disposed between the island gate 260 and the first gate 210 and may contact the bridge portion 250B.

Although the separation region 310 according to an embodiment of the present disclosure is illustrated as including the first separation layer 312 and the second separation layer 314, the separation region 310 may be formed of a single layer in an embodiment. For example, in an embodiment, the separation region 310 may be filled with one layer including silicon oxide or one layer including silicon nitride.

The separation region 310 may include an insulating material capable of electrically isolating adjacent second gates 250.

The region where the separation region 310 is formed may be referred to also as a cut region. The cut region may be formed through an etching process.

The cut region may be a region formed by removing a portion of a second pre-gate located between the island gate 260 and the first gate 210 before the second gate 250 is formed.

The second pre-gate may refer to a gate disposed before two second gates 250 which extend with the first gate 210 interposed therebetween and are electrically isolated from one another.

By forming the cut region, the second gates 250 adjacent to each other with the first gate 210 between may be electrically isolated from each other.

The contact plug 400 may be disposed in contact with the second gate 250 and the island gate 260. As the island gate 260 is formed, a margin on the layout in which the contact plug 400 is disposed may be secured.

The contact plug 400 may include a conductive material. A control signal may be provided from an external device, such as a control circuit, to the second gate 250 through the contact plug 400.

The control signal provided to the second gate 250 through the contact plug 400 may be a word line control signal, and each second gate 250 may operate as a word line by the control signal.

The contact plug 400 may extend in the third direction D3, and one side of the contact plug 400 that is not in contact with the second gate 250 may contact the control circuit.

According to the embodiment of FIG. 2A, the contact plugs 400 may be sparsely spaced apart from each other in the second direction D2.

Each of the contact plugs 400 may be disposed in contact with the second gate 250 and the island gate 260.

With the inclusion of the island gate 260, the contact area between the contact plug 400 and the island gate 260 can be more reliably secured during the formation of the contact plug. As a result, the contact stability between the plug and gate structure is enhanced.

The contact plugs 400 may contact the island gates 260 which are positioned adjacent to the opposite ends of the first gate 210. The contact plugs 400 may be spaced apart from each other in a diagonal direction with respect to the center of the first gate 210. Since the control signal is provided through the contact plugs 400, the contact plugs 400 may be spaced apart from each other by a preset distance. This configuration supports stable control signal transmission through the contact plugs 400.

In FIG. 2B, the bit line 600 included in the substrate is illustrated by a dotted line.

The first gate 610 may be disposed over the bit line 600 extending in the second direction D2. A first gate insulating layer 620 may be formed between the first gate 610 and an active region 630 and may surround the first gate 610.

A second gate insulating layer 640 may be formed between the active region 630 and the second gate 650 and may be formed outside the first gate insulating layer 620 to surround the first gate 610. The first and second gate insulating layers 620 and 640 may include an insulating material, and the insulating material may include, for example, silicon oxide, silicon nitride, metal oxide, metal oxy nitride, metal silicate, a high-k material, a ferroelectric material, an anti-ferroelectric material, or a combination thereof. The first gate insulating layer 620 may include SiO₂, Si₃N₄, HfO₂, Al₂O₃, ZrO₂, AlON, HfON, HfSiO, HfSiON, or a combination thereof.

The second gate 650 may include a conductive material, such as, for example, a metal-base material, a semiconductor material, or a combination thereof. For example, in an embodiment, the second gate 650 may include a single titanium nitride film.

A gate spacer 690 may be a layer that electrically isolates the adjacent second gates 650 and may include, for example, silicon nitride.

The island gates 660 may be disposed at opposite ends of the first gate 610 in the first direction D1.

The island gate 660 may contact the second gate 650. The island gate 660 may include a conductive material such as, for example, a metal-base material, a semiconductor material, or a combination thereof. For example, in an embodiment, the island gate 660 may include a single titanium nitride film.

The semiconductor device may include a separation region 710 that electrically isolates the adjacent second gates 650, and the separation region 710 may be disposed at the opposite ends of the second gate 650 in the first direction D1.

In an embodiment, the second gate 650 may be designed without a bridge portion.

The bridge portion may not be formed by making the distance between the first gate 610 and the island gate 660 less than a preset distance. The second gate 650 may not be formed between the first gate 610 and the island gate 660.

According to an embodiment, the second gate 650 may be formed in contact with the island gate 660 by etching a first island gate insulating layer 670 and a second island gate insulating layer 680 located on one sidewall of the island gate 660 before the second gate 650 is formed.

The first island gate insulating layer 670 and the second island gate insulating layer 680 may be formed between the second gate 650 that is not in contact with the island gate 660 and the island gate 660. The island gate 660 may be disposed in contact with one second gate 650.

In addition, since the separation region 710 is disposed in contact with the opposite ends of the second gate 650, the adjacent second gates 650 may be electrically isolated from each other.

The separation region 710 may include a first separation layer 712 and a second separation layer 714. For example, the first separation layer 712 may include silicon nitride, and the second separation layer 714 may include silicon oxide.

The separation region 710 according to an embodiment of the present disclosure as illustrated in FIG. 2B includes the first separation layer 712 and the second separation layer 714. However, the separation region 710 may also be formed of a single layer in some embodiments. For example, the separation region 710 may be filled with one layer including silicon oxide or one layer including silicon nitride. The separation region 710 may be disposed in contact with the opposite ends of the second gate 650 in the first direction D1 and may be formed in a cut region that electrically isolates the adjacent second gates 650. The second gates 650 may be electrically isolated from each other by forming the cut region at the opposite ends of the second gates 650 through an etching process.

A contact plug 800 may contact the second gate 650 which in turn is in contact with the island gate 660. Since the island gate 660 is formed in contact with the second gate 650, a sufficient layout margin for contact of the contact plug 800 may be secured.

The contact plug 800 may contact the island gate 660 and/or the second gate 650, and a control signal may be provided to the second gate 650 through the contact plug 800.

A plurality of contact plugs 800 may be disposed in a zigzag configuration with respect to the opposite ends of the first gate 610. The contact plugs 800 may be disposed to correspond to the island gates 660 and the second gates 650. One contact plug 800 may be disposed to correspond to each one of the island gates 660 and the second gates 650.

The contact plugs 800 may be spaced apart from each other in a diagonal direction with respect to the center of the first gate 610. Since the control signal is provided through the contact plugs 800, the contact plugs 800 may be spaced apart from each other by a preset distance.

In FIG. 2C, the bit line 1000 included in the substrate is illustrated by a dotted line.

The first gate 1010 may be disposed over the bit line 1000 extending in the second direction D2, and a first gate insulating layer 1020 may be formed between the first gate 1010 and an active region 1030. The first gate insulating layer 1020 may surround the first gate 1010.

A second gate insulating layer 1040 may be formed between the active region 1030 and the second gate 1050 and may be formed outside the first gate insulating layer 1020 to surround the first gate 1010. The first gate insulating layer 1020 and the second gate insulating layer 1040 may include an insulating material, such as, for example, silicon oxide, silicon nitride, metal oxide, metal oxy nitride, metal silicate, a high-k material, a ferroelectric material, an anti-ferroelectric material, or a combination thereof. The first gate insulating layer 220 may include SiO₂, Si₃N₄, HfO₂, Al₂O₃, ZrO₂, AlON, HfON, HfSiO, HfSiON, or a combination thereof.

The second gate 1050 may include a conductive material, such as, for example, a metal-base material, a semiconductor material, or a combination thereof. For example, in an embodiment, the second gate 1050 may include a single titanium nitride film.

A first island gate insulating layer 1070 and a second island gate insulating layer 1080 may be formed between the island gate 1060 and the first gate 1010. A gate spacer 1090 may electrically isolate the adjacent second gates 1050. A second interlayer insulating layer 1100 may be a layer that separates the adjacent gate spacers 1090.

The island gates 1060 may be disposed at the opposite ends of the first gate 1010 in the first direction (e.g., the direction D1). The island gate 1060 may contact the second gate 1050. The island gate 1060 may include a conductive material.

The conductive material included in the island gate 1060 may include, for example, a metal-base material, a semiconductor material, or a combination thereof. For example, in an embodiment, the island gate 1060 may include a single titanium nitride film.

The semiconductor device may include a separation region 1110 that electrically isolates the adjacent second gates 1050, and the separation region 1110 may be disposed at the opposite ends of the second gate 1050 in the first direction D1.

According to an embodiment, the second gate 1050 may not include a bridge portion. The second gate 1050 may not be formed between the first gate 1010 and the island gate 1060.

The bridge portion may not be formed by making the distance between the first gate 1010 and the island gate 1060 less than a preset distance.

According to an embodiment, the second gate 1050 may be formed in the direction in which the first gate 1010 extends, and the first gate insulating layer 1020 and the second gate insulating layer 1040 formed along the sidewall of the first gate 1010 may be formed between the first gate 1010 and the second gate 1050.

The second gate 1050 may be electrically isolated from the first gate 1010 and the active region 1030 and may be connected with the island gate 1060 by a contact plug 1200.

In addition, since the separation region 1110 is disposed in contact with the opposite ends of the second gate 1050 in the first direction (e.g., the direction D1), the adjacent second gates 1050 may be electrically isolated from each other.

The separation region 1110 may include a first separation layer 1112 and a second separation layer 1114. The first separation layer 1112 may include silicon nitride, and the second separation layer 1114 may include silicon oxide.

The separation region 1110 may be disposed at the opposite ends of the second gate 1050 and may be formed in a cut region that separates the adjacent second gates 1050. The second gates 1050 may be electrically isolated from each other by forming the cut region at the opposite ends of the second gates 1050 through an etching process.

The semiconductor device may reduce a process step by omitting an etching process for connection of the island gate 1060 and the second gate 1050 when the second gate 1050 is formed.

The contact plug 1200 may contact the island gate 1060 and/or the second gate 1050, and a control signal may be provided to the second gate 1050 through the contact plug 1200.

The contact plug 1200 may be disposed in zigzags with respect to the opposite ends of the first gate 1010. The contact plug 1200 may be disposed to correspond to one island gate 1060 and one second gate 1050. More specifically, for example, the contact plugs 1200 may be disposed to correspond to the island gates 1060 and the second gates 1050. Also, as an example, one contact plug 1200 may be disposed to correspond to each one of the island gates 1060 and the second gates 1050.

The contact plugs 1200 may be spaced apart from each other in a diagonal direction with respect to the center of the first gate 1010. Since the control signal is provided through the contact plugs 1200, the contact plugs 1200 may be spaced apart from each other by a preset distance.

FIG. 2D is a sectional view of the semiconductor device taken along cutting line X1-X1′ of FIG. 2A.

Cutting line X1-X1′ may be a cutting line that extends along the center of the contact plug 400 and passes through the center of the island gate 260.

Referring to FIG. 2D, a first interlayer insulating layer 120 may be disposed over a substrate layer 110, and a first bit line insulating layer 130 may be disposed over the first interlayer insulating layer 120. In addition, a second bit line insulating layer 130 may be disposed over the first bit line insulating layer 140, and the island gate 260 may be disposed over the second bit line insulating layer 140.

The first island gate insulating layer 270 and the second island gate insulating layer 280 may be disposed along the side surface of the island gate 260, and the second gate 250 may be disposed along the sidewall of the second island gate insulating layer 280.

The second gate 250 may be surrounded by the gate spacer 290.

The contact plug 400 may contact the second gate 250 and the island gate 260.

The contact plug 400 may be formed in a region obtained by removing at least portions of the second gate 250, the island gate 260, the first island gate insulating layer 270, and the second island gate insulating layer 280.

The contact plug 400 may include a conductive material, and the second gate 250 and the island gate 260 may be electrically connected through the contact plug 400.

FIG. 2E is a sectional view of the semiconductor device taken along cutting line X2-X2′ of FIG. 2B.

Cutting line X2-X2′ may be a cutting line that extends along the center of the contact plug 800 and passes through the center of the island gate 260.

Referring to FIG. 2E, a first interlayer insulating layer 520 may be disposed over a substrate layer 510, and a first bit line insulating layer 530 may be disposed over the first interlayer insulating layer 520. In addition, a second bit line insulating layer 540 may be disposed over the first bit line insulating layer 530, and the island gate 660 may be disposed over the second bit line insulating layer 540.

The first island gate insulating layer 670 and the second island gate insulating layer 680 may be disposed along one side surface of the island gate 660.

According to the embodiment of FIG. 2E, the second gate 650 may contact the second island gate insulating layer 680. The second gate 650 disposed at one side of the island gate 660 may be separated from the island gate 660 by the first island gate insulating layer 670 and the second island gate insulating layer 680.

In addition, the first island gate insulating layer 670 and the second island gate insulating layer 680 disposed on an opposite side surface of the island gate 660 may be removed, and the second gate 650 may directly contact the island gate 660.

The gate spacer 690 may be disposed to surround the second gate 650.

The contact plug 800 may contact the island gate 660 and the second gate 650 that is in direct contact with the island gate 660.

The contact plug 800 may be formed in a region obtained by removing at least portions of the second gate 650, the island gate 660, and the gate spacer 690.

The contact plug 800 may include a conductive material.

FIG. 2F is a sectional view of the semiconductor device taken along cutting line X3-X3′ of FIG. 2C.

Cutting line X3-X3′ may be a cutting line that extends along the center of the contact plug 1200 and passes through the center of the island gate 1060.

Referring to FIG. 2F, a first interlayer insulating layer 920 may be disposed over a substrate layer 910, and a first bit line insulating layer 930 may be disposed over the first interlayer insulating layer 920. In addition, a second bit line insulating layer 940 may be disposed over the first bit line insulating layer 930, and the island gate 1060 may be disposed over the second bit line insulating layer 940.

The first island gate insulating layer 1070 and the second island gate insulating layer 1080 may be disposed along the side surface of the island gate 1060, and the second gate 1050 may be disposed along the sidewall of the second island gate insulating layer 1080.

The second gate 1050 may be surrounded by the gate spacer 1090.

The contact plug 1200 may contact the second gate 1050 and the island gate 1060.

The contact plug 1200 may be formed in a region obtained by removing at least portions of the second gate 1050, the island gate 1060, the first island gate insulating layer 1070, and the second island gate insulating layer 1080.

The contact plug 1200 may include a conductive material, and the second gate 1050 and the island gate 1060 may be electrically connected through the contact plug 1200.

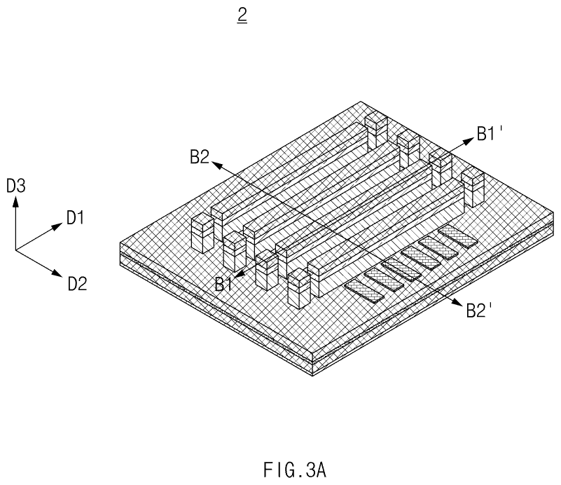

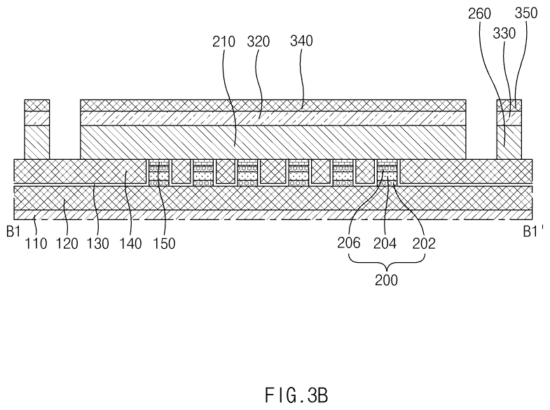

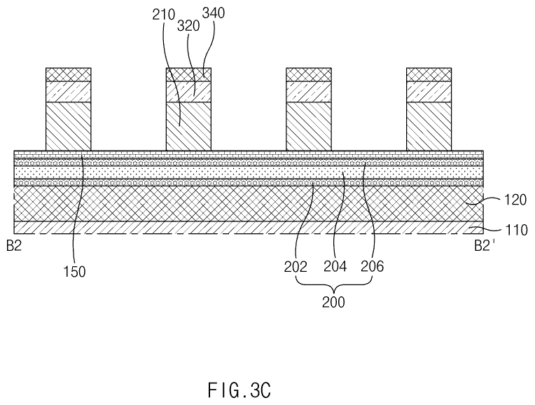

FIGS. 3A to 16A, FIGS. 3B to 16B, and FIGS. 3C to 15C are views for describing fabrication operations of the semiconductor device according to an embodiment of the present disclosure.

FIG. 3A is a perspective view 2 illustrating a fabrication operation of the semiconductor device for forming the first gate 210 over the bit line.

In the perspective view 2, a shape in which the first gates are disposed over the plurality of bit lines extending in the second direction (e.g., the direction D2) and the island gates are disposed at the opposite ends of the first gate is illustrated.

FIG. 3B is a sectional view taken along line B1-B1′ of FIG. 3A, and FIG. 3C is a sectional view taken along line B2-B2′ of FIG. 3A.

FIG. 3B is a sectional view illustrating a cross-section of the first gate 210 in the first direction (e.g., the direction D1).

FIG. 3C is a sectional view illustrating cross-sections of the plurality of first gates 210 in the second direction (e.g., the direction D2).

Referring to FIGS. 3B and 3C, the first interlayer insulating layer 120 may be disposed over the substrate layer 110, and the bit line 200 may be disposed over the first interlayer insulating layer 120.

The bit line 200 may include a plurality of layers. For example, the bit line 200 of FIG. 3B may include a first bit line layer 202, a second bit line layer 204, and a third bit line layer 206. According to an embodiment, the first bit line layer 202 and the third bit line layer 206 may include titanium nitride (TiN), and the second bit line layer 204 may include tungsten (W).

The bit line 200 may be formed through an etching process using a mask after the plurality of layers are deposited. More specifically, after the deposition of the plurality of layers that make up the bit line 200, an etching process is carried out to define the bit line structure. This etching process typically involves applying a patterned mask to the top surface of the multilayer stack, which selectively protects certain areas while exposing others. The exposed regions are then etched away using a suitable etchant, thereby forming the desired bit line geometry. This approach enables high-resolution patterning and helps ensure dimensional accuracy and layer integrity.

The bit lines 200 may be electrically isolated from each other by a plurality of layers. For example, the first bit line insulating layer 130 may be disposed along the sidewalls of the bit lines 200, and the second bit line insulating layer 140 may be disposed between the bit lines 200.

The first bit line insulating layer 130 may include, for example, silicon nitride, and the second bit line insulating layer 140 may include silicon oxide.

The first bit line insulating layer 130 and the second bit line insulating layer 140 may separate the adjacent bit lines 200 from each other.

A third bit line insulating layer 150 may be disposed over each of the bit lines 200. The third bit line insulating layer 150 may include an insulating material, such as, for example, silicon oxide, silicon nitride, silicon carbonate, metal oxide, metal oxy nitride, metal silicate, a high-k material, a ferroelectric material, an anti-ferroelectric material, or a combination thereof.

The first gate 210 and the bit line 200 may be electrically isolated from each other by the third bit line insulating layer 150.

The first gate 210 may include a metal, a metal mixture, a metal alloy, titanium nitride, tungsten, poly silicon, or a combination thereof. For example, the first gate 210 may include titanium nitride.

The first gate 210 may be disposed such that it at least partially overlaps with the bit line 200. The first gate 210 may be formed by sequentially forming a titanium nitride layer, a silicon nitride layer, and a silicon oxide layer on the bit line 200 and etching the layers using a mask including a spin on carbon (Soc) layer and a SiON layer.

In addition, through the etching process, the island gate 260 may be formed together with the first gate 210. For example, the first gate 210 and the island gate 260 may be initially formed as a single integrated line and then separated through the etching(cutting) process.

The island gate 260 may include a metal, a metal mixture, a metal alloy, titanium nitride, tungsten, poly silicon, or a combination thereof. For example, the island gate 260 may include titanium nitride.

A first gate upper insulating layer 320 and a first gate upper protection layer 340 formed over the first gate 210 may prevent damage to the first gate 210 during the semiconductor device fabrication process.

Likewise, an island gate upper insulating layer 330 and an island gate upper protection layer 350 formed over the island gate 260 may prevent damage to the island gate 260 during the semiconductor device fabrication process.

In addition, the first gate upper insulating layer 320 may electrically isolate the first gate 210 from other components (e.g., the active region) included in the semiconductor device, and the island gate upper insulating layer 330 may electrically isolate the island gate 260 from other components (e.g., the active region) included in the semiconductor device.

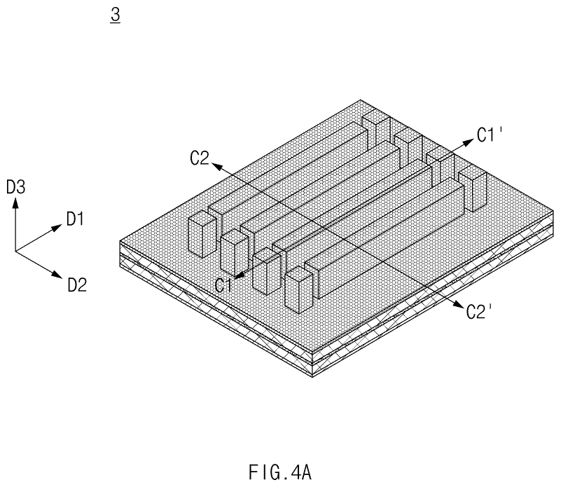

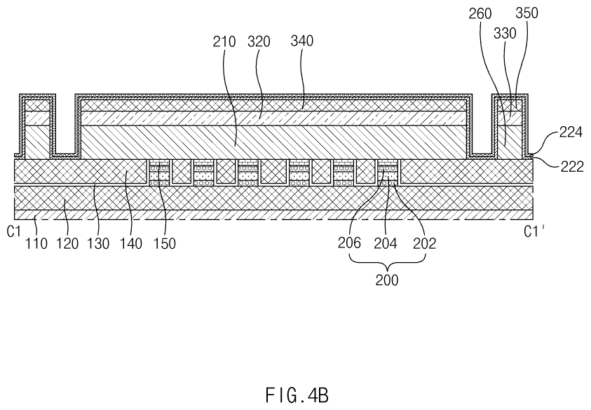

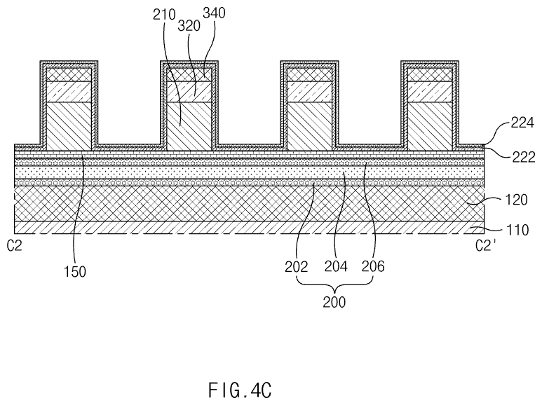

FIG. 4A is a perspective view 3 illustrating a fabrication operation of the semiconductor device for forming a first pre-gate insulating layer 222 and an insulating film protection layer 224 over the first gate 210.

In the perspective view 3, a shape in which a plurality of layers are disposed over the first gate 210 is illustrated.

FIG. 4B is a sectional view taken along line C1-C1′ of FIG. 4A, and FIG. 4C is a sectional view taken along line C2-C2′ of FIG. 4A.

Referring to FIGS. 4B and 4C, the first pre-gate insulating layer 222 and the insulating film protection layer 224 may be formed over the first gate 210 and the third bit line insulating layer 150.

The first pre-gate insulating layer 222 may include silicon oxide. The insulating film protection layer 224 may include poly silicon.

By forming the insulating film protection layer 224, the first gate insulating layer 220 formed from the first pre-gate insulating layer 222 may be protected during the fabrication process of the active region 230 in contact with the bit line 200.

By placing the insulating film protection layer 224, damage to the first gate insulating layer 220 by plasma during an etching process may be prevented. For example, by providing the insulating film protection layer 224, a decrease in the thickness of the first gate insulating layer 220 or a surface defect caused by plasma may be prevented.

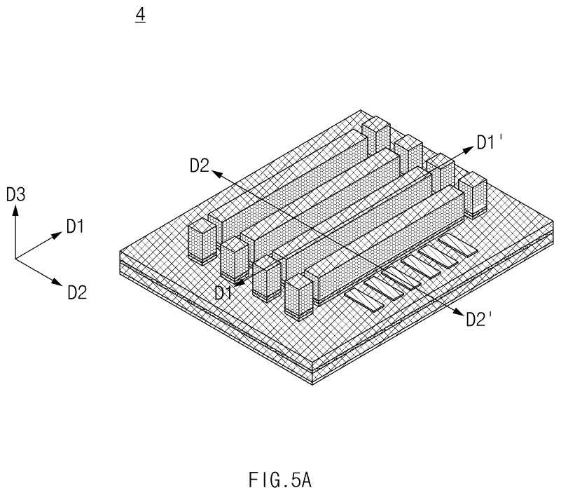

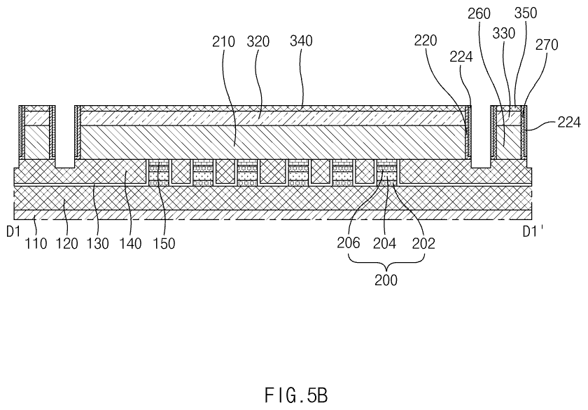

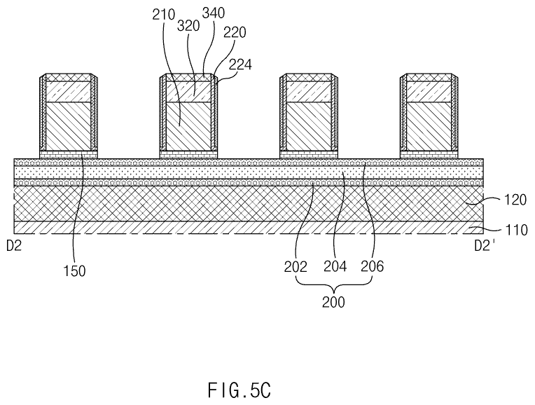

FIG. 5A is a perspective view 4 illustrating a fabrication operation of the semiconductor device for forming the first gate insulating layer 220 and the first island gate insulating layer 270 by etching the first gate 210 and the first pre-gate insulating layer 222.

In the perspective view 4, a shape in which the first gate insulating layer 220 and the first island gate insulating layer 270 are formed and at least a portion of the insulating film protection layer 224 is removed is illustrated.

FIG. 5B is a sectional view taken along line D1-D1′ of FIG. 5A, and FIG. 5C is a sectional view taken along line D2-D2′ of FIG. 5A.

Referring to FIGS. 5B and 5C, a portion of the first pre-gate insulating layer 222 may be removed, and the first gate insulating layer 220 and the first island gate insulating layer 270 may be formed.

Since at least a portion of the first pre-gate insulating layer 222 is removed through plasma etching, the first pre-gate insulating layer 222 may be separated into the first gate insulating layer 220 and the first island gate insulating layer 270. For example, the first gate insulating layer 220 and the first island gate insulating layer 270 may be remaining regions after the first pre-gate insulating layer 222 is partially removed.

Due to the etching process, a portion of the second bit line insulating layer 140 may be removed, and at least a portion of the third bit line insulating layer 150 disposed over the bit line 200 between the first gates 210 may be removed to expose the bit line 200.

After the etching process, the insulating film protection layer 224 that overlaps the first gate insulating layer 220 and the first island gate insulating layer 270 may be selectively left.

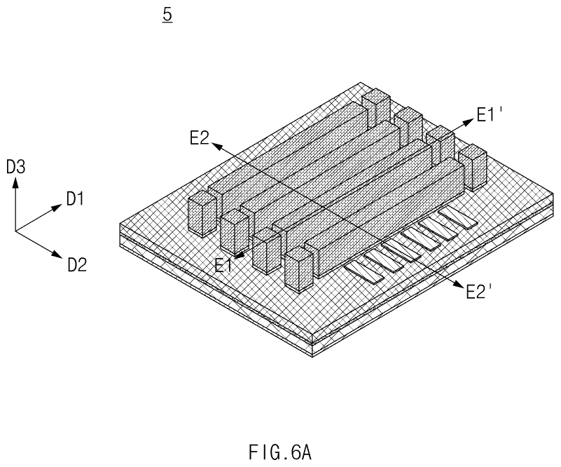

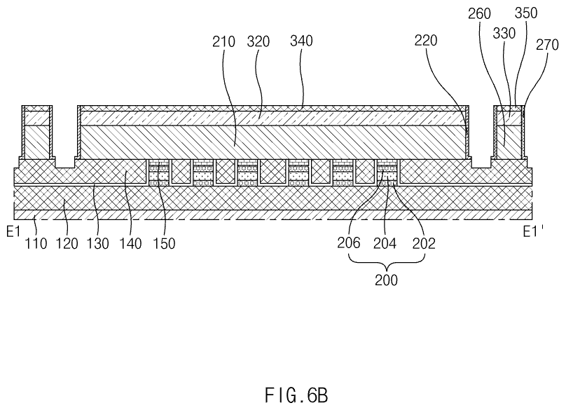

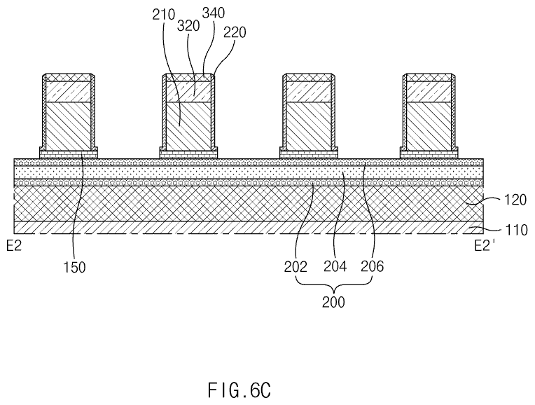

FIG. 6A is a perspective view 5 illustrating a fabrication operation of the semiconductor device for removing the insulating film protection layer 224.

In the perspective view 5, a shape in which the insulating film protection layer 224 that protects the first gate insulating layer 220 and the first island gate insulating layer 270 during the etching process is removed is illustrated.

FIG. 6B is a sectional view taken along line E1-E1′ of FIG. 6A, and FIG. 6C is a sectional view taken along line E2-E2′ of FIG. 6A.

Referring to FIGS. 6B and 6C, the selectively left insulating film protection layer 224 may be removed. Since the insulating film protection layer 224 is removed, the first gate insulating layer 220 and the first island gate insulating layer 270 may be exposed to the outside.

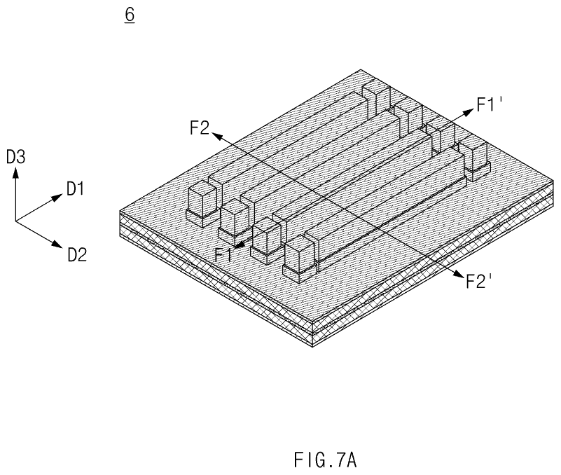

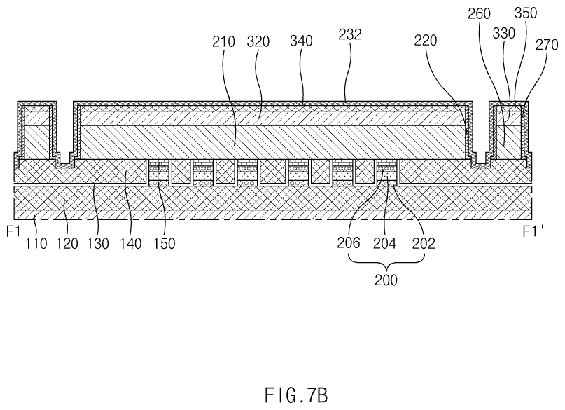

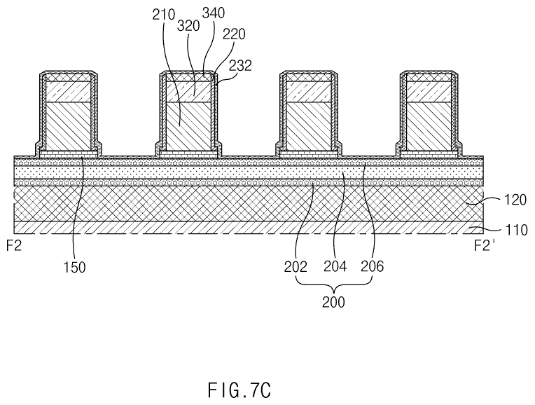

FIG. 7A is a perspective view 6 illustrating a fabrication operation of the semiconductor device for forming an oxide semiconductor layer 232 on the first gate insulating layer 220 and the first island gate insulating layer 270.

FIG. 7B is a sectional view taken along line F1-F1′ of FIG. 7A, and FIG. 7C is a sectional view taken along line F2-F2′ of FIG. 7A.

Referring to FIGS. 7B and 7C, the oxide semiconductor layer 232 may be formed on the bit line 200, the first gate insulating layer 220, and the first island gate insulating layer 270. In particular, the bit line 200 may be electrically connected with the oxide semiconductor layer 232.

The first gate 210 and the island gate 260 may be electrically isolated from the oxide semiconductor layer 232 by the first gate insulating layer 220 and the first island gate insulating layer 270, respectively.

For example, the oxide semiconductor layer 232 may include a material such as IGZO and may be formed by an atomic layer deposition method.

When the oxide semiconductor layer 232 is formed by the atomic layer deposition method, the thickness may be easily adjusted, and the film quality may be uniformly formed. Thus, the electrical characteristics of the semiconductor device may be improved.

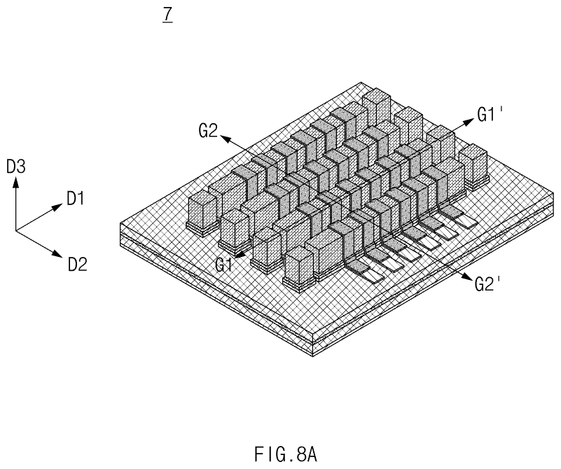

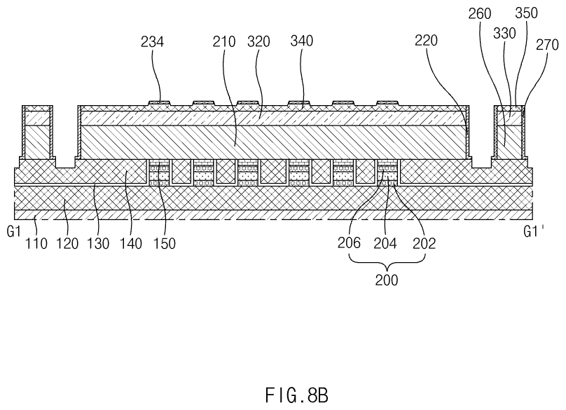

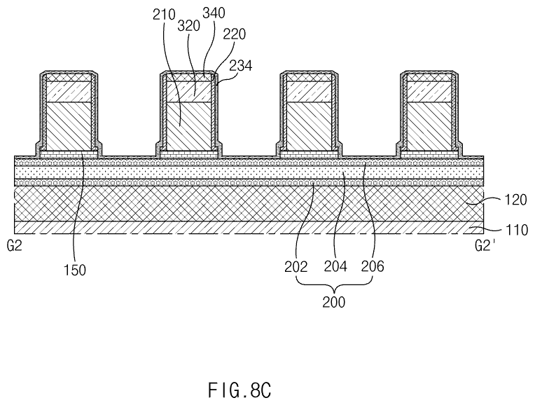

FIG. 8A is a perspective view 7 illustrating a fabrication operation of the semiconductor device for forming a pre-active region 234 by removing at least a portion of the oxide semiconductor layer 232.

FIG. 8B is a sectional view taken along line G1-G1′ of FIG. 8A, and FIG. 8C is a sectional view taken along line G2-G2′ of FIG. 8A.

Referring to FIGS. 8B and 8C, the oxide semiconductor layer 232 may be separated into a plurality of pre-active regions 234 in the first direction (e.g., the direction D1).

For example, each of the plurality of pre-active regions 234 formed from the oxide semiconductor layer 232 may be electrically connected to the bit line 200.

According to an embodiment, a mask including a spin on carbon (SOC) layer and a SiON layer may be formed on the oxide semiconductor layer 232, and the pre-active regions 234 may be selectively formed by selectively etching the oxide semiconductor layer 232.

The oxide semiconductor layer 232 in the region where the pre-active region 234 is not formed may be removed. For example, the oxide semiconductor layer 232 disposed over the upper portion and the sidewall of the island gate 260 may be entirely removed and the oxide semiconductor layer 232 disposed over the upper portion and the sidewall of the first gate 210 may be partially removed through etching.

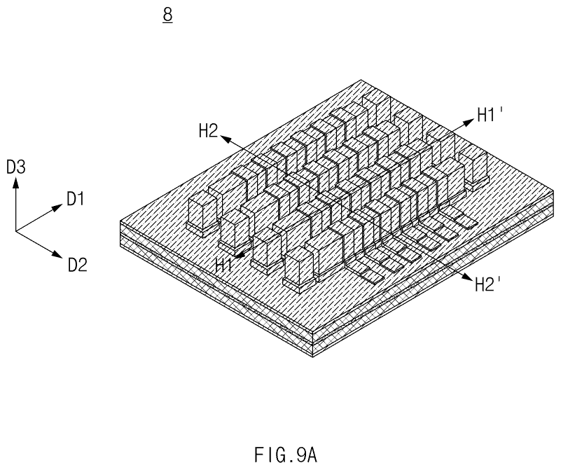

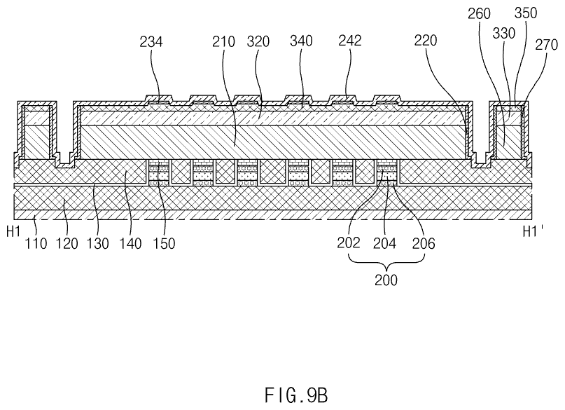

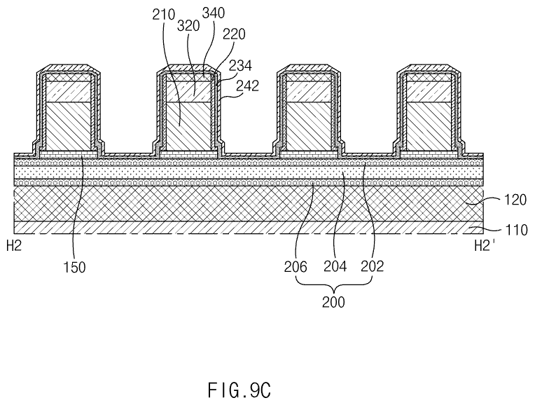

FIG. 9A is a perspective view 8 illustrating a fabrication operation of the semiconductor device for forming a second pre-gate insulating layer 242 over the pre-active region 234.

FIG. 9B is a sectional view taken along line H1-H1′ of FIG. 9A, and FIG. 9C is a sectional view taken along line H2-H2′ of FIG. 9A.

Referring to FIGS. 9B and 9C, the second pre-gate insulating layer 242 may be formed over the plurality of pre-active regions 234. The second pre-gate insulating layer 242 may include an insulating layer of silicon oxide and may electrically isolate the pre-active region 234 from the second gate 250.

The second pre-gate insulating layer 242 may be formed to cover the sidewall and the upper portion of the first gate 210 and may be formed to cover the sidewall and the upper portion of the island gate 260.

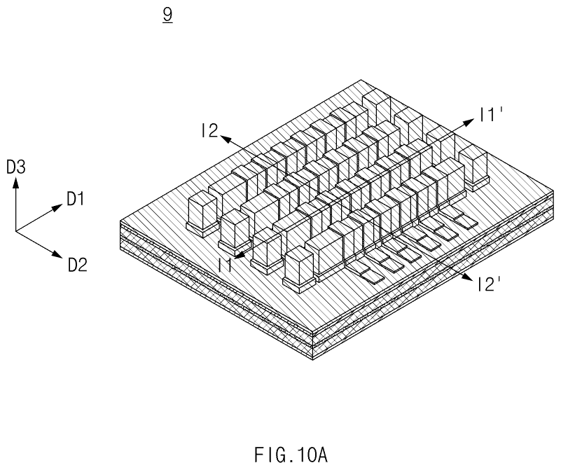

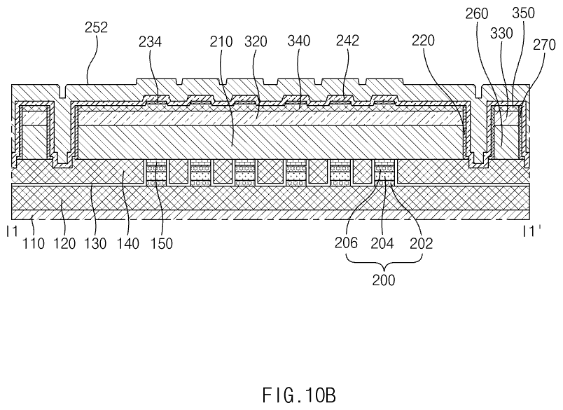

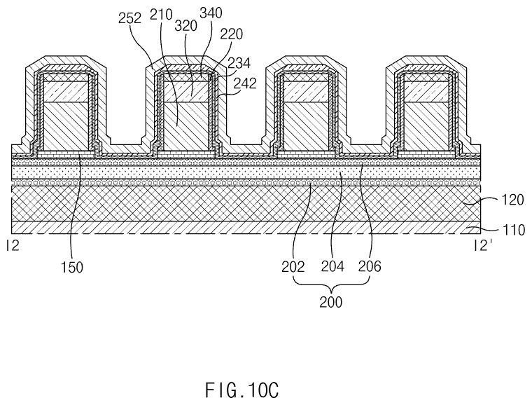

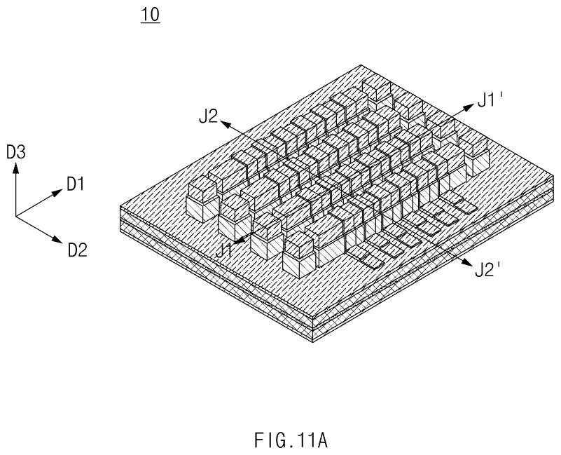

FIG. 10A is a perspective view 9 illustrating a fabrication operation of the semiconductor device for forming a conductive material layer 252 over the second pre-gate insulating layer 242.

FIG. 10B is a sectional view taken along line I1-I1′ of FIG. 10A, and FIG. 10C is a sectional view taken along line I2-I2′ of FIG. 10A.

Referring to FIGS. 10B and 10C, the conductive material layer 252 may be formed over the second pre-gate insulating layer 242. The conductive material layer 252 may include a conductive material such as titanium nitride.

The conductive material layer 252 may be formed to surround the sidewall and the upper portion of the first gate 210 and the island gate 260. In particular, the conductive material layer 252 may be formed between the first gate 210 and the island gate 260.

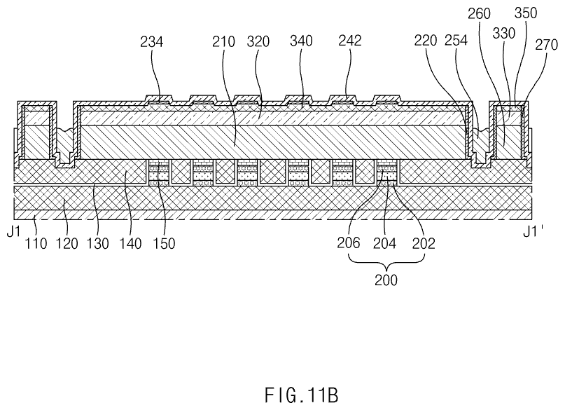

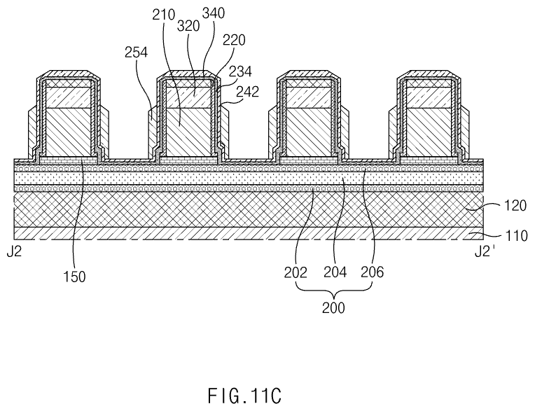

FIG. 11A is a perspective view 10 illustrating a fabrication operation of the semiconductor device for forming a second pre-gate 254 by etching at least a portion of the conductive material layer 252.

FIG. 11B is a sectional view taken along line J1-J1′ of FIG. 11A, and FIG. 11C is a sectional view taken along line J2-J2′ of FIG. 11A.

Referring to FIGS. 11B and 11C, the second pre-gate 254 may be formed by selectively etching the conductive material layer 252.

The second pre-gate 254 may be formed by selectively etching the conductive material layer 252 disposed over the first gate 210 and the island gate 260.

According to an embodiment, the second pre-gate 254 may be formed to have the same height as the first gate 210. Among the regions included in the second pre-gate 254, the region disposed between the first gate 210 and the island gate 260 may be the bridge portion of the second gate 250.

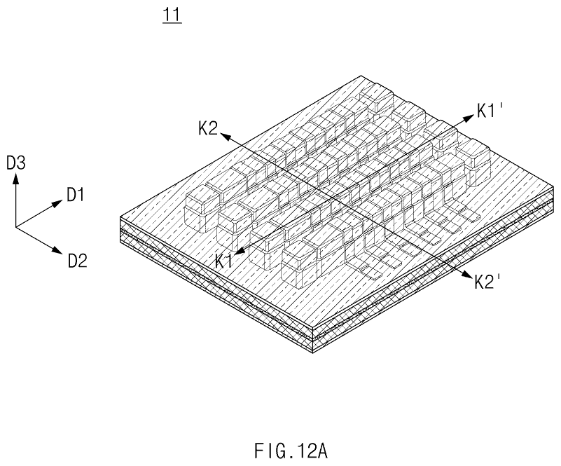

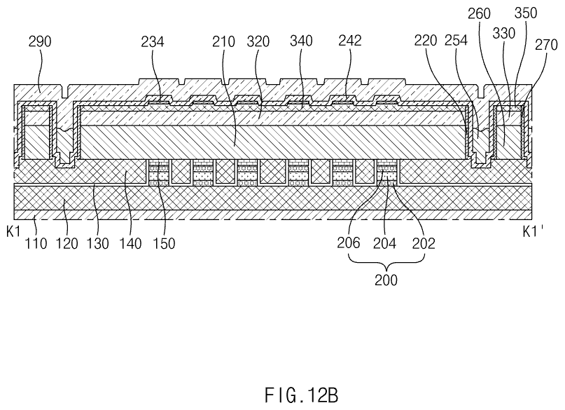

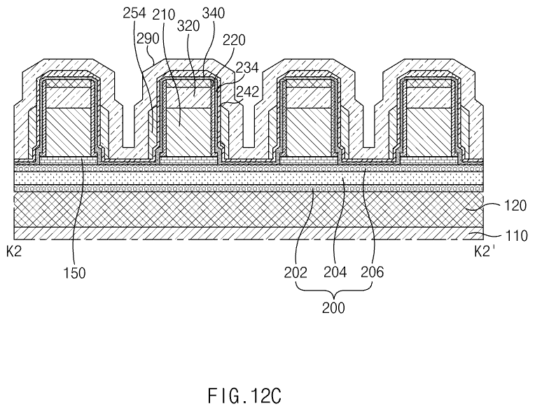

FIG. 12A is a perspective view 11 illustrating a fabrication operation of the semiconductor device for forming the gate spacer 290 on the second pre-gate 254 and the second pre-gate insulating layer 242.

FIG. 12B is a sectional view taken along line K1-K1′ of FIG. 12A, and FIG. 12C is a sectional view taken along line K2-K2′ of FIG. 12A.

Referring to FIGS. 12B and 12C, the gate spacer 290 may be formed over the second pre-gate 254.

According to an embodiment, the gate spacer 290 may include silicon nitride. The gate spacer 290 may electrically isolate the second pre-gate 254 from other components included in the semiconductor device. For example, the gate spacer 290 may electrically isolate the adjacent second pre-gates 254.

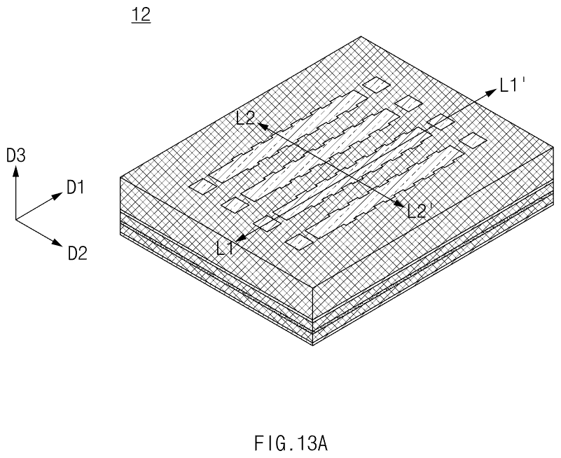

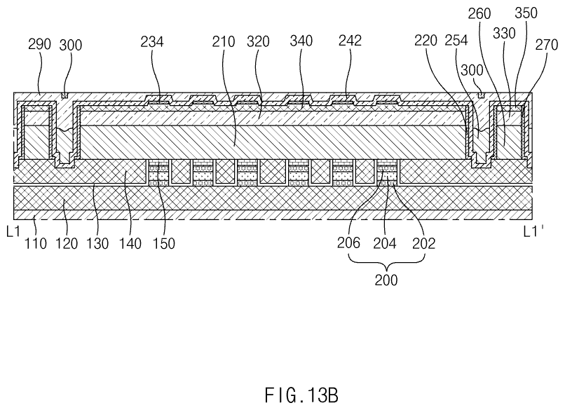

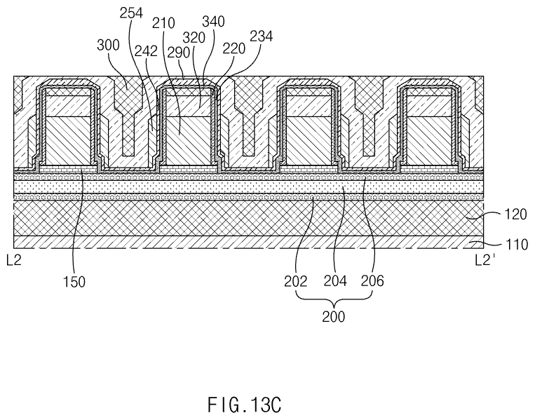

FIG. 13A is a perspective view 12 illustrating a fabrication operation of the semiconductor device for forming the second interlayer insulating layer 300 between the gate spacers 290 and removing a portion of the gate spacer 290 and a portion of the second interlayer insulating layer 300.

FIG. 13B is a sectional view taken along line L1-L1′ of FIG. 13A, and FIG. 13C is a sectional view taken along line L2-L2′ of FIG. 13A.

Referring to FIGS. 13B and 13C, the second interlayer insulating layer 300 may be formed between the gate spacers 290.

According to an embodiment, the second interlayer insulating layer 300 may include silicon oxide.

The gate spacer 290 and the second interlayer insulating layer 300 may be at least partially removed through a chemical mechanical polishing (CMP) process.

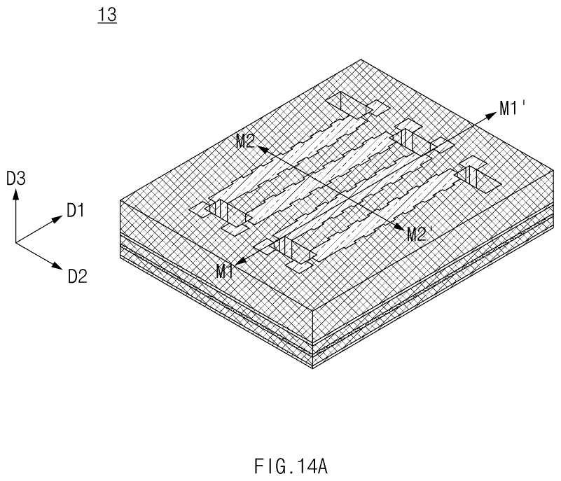

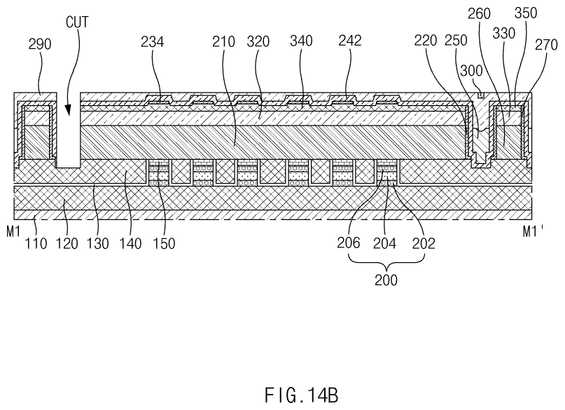

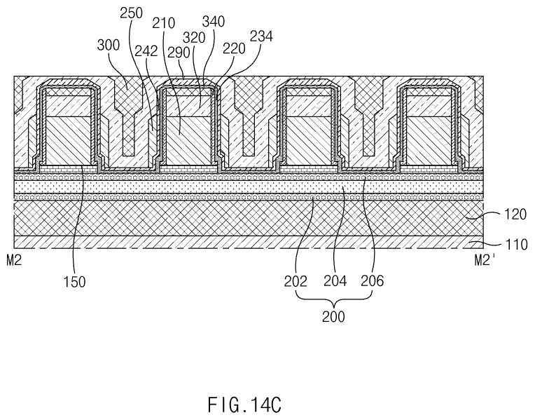

FIG. 14A is a perspective view 13 illustrating a fabrication operation of the semiconductor device for forming the second gate 250 and a cut region CUT. The operation may include etching a portion of the second pre-gate 254, a portion of the first gate insulating layer 220, and a portion of the second pre-gate insulating layer 242 to form the second gate 250 and the cut region CUT.

FIG. 14B is a sectional view taken along line M1-M1′ of FIG. 14A, and FIG. 14C is a sectional view taken along line M2-M2′ of FIG. 14A.

Referring to FIGS. 14B and 14C, the cut region CUT may be formed at one end of the first gate 210.

The cut region CUT may be formed through an etching process. By forming the cut region CUT, the second pre-gate 254 formed over the both sidewalls of the first gate 210 may be separated into two second gates 250.

According to an embodiment, the cut region CUT may be formed by etching a portion of the first gate 210. The cut region CUT may be formed through selective etching using a mask. As illustrated in FIG. 14A, the cut region CUT may be formed between two first gates 210 and may be sparsely formed in the second direction (e.g., the direction D2).

The cut region CUT may remove at least a portion of the second pre-gate 254 disposed between the first gate 210 and the island gate 260. The second pre-gate 254 that is disposed between the first gate 210 and the island gate 260 and is not removed by the cut region CUT may be the bridge portion 250B illustrated in the FIG. 2A.

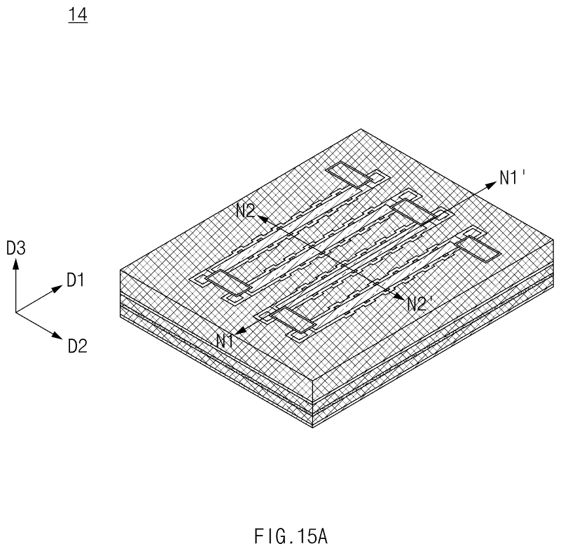

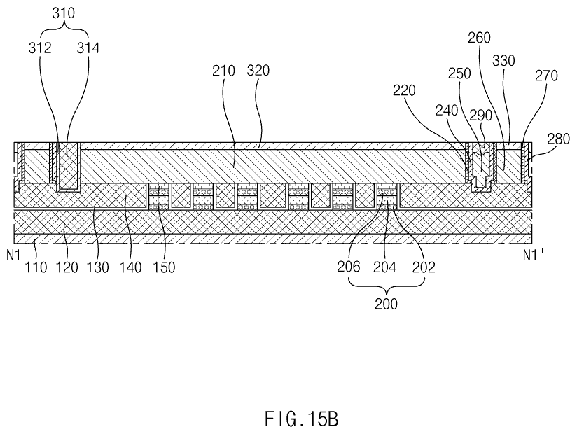

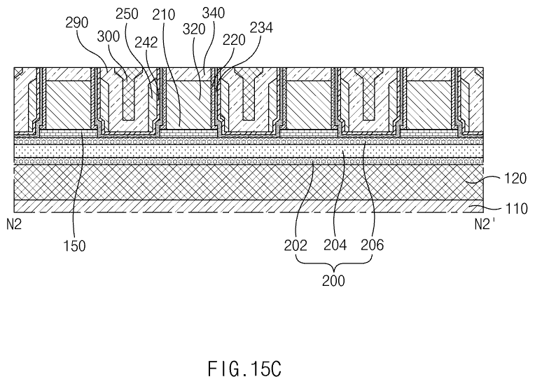

FIG. 15A is a perspective view 14 illustrating a fabrication operation of the semiconductor device for forming the separation region 310 in the cut region CUT.

FIG. 15B is a sectional view taken along line N1-N1′ of FIG. 15A, and FIG. 15C is a sectional view taken along line N2-N2′ of FIG. 15A.

Referring to FIGS. 15B and 15C, the first separation layer 312 and the second separation layer 314 may be formed in the cut region CUT.

The first separation layer 312 may include silicon nitride, and the second separation layer 314 may include silicon oxide.

The first separation layer 312 and the second separation layer 314 may be formed through deposition and etching. For example, formation of the first and second separation layers may include sequential deposition—such as chemical vapor deposition (CVD)—followed by precise etching to define the layer boundaries.

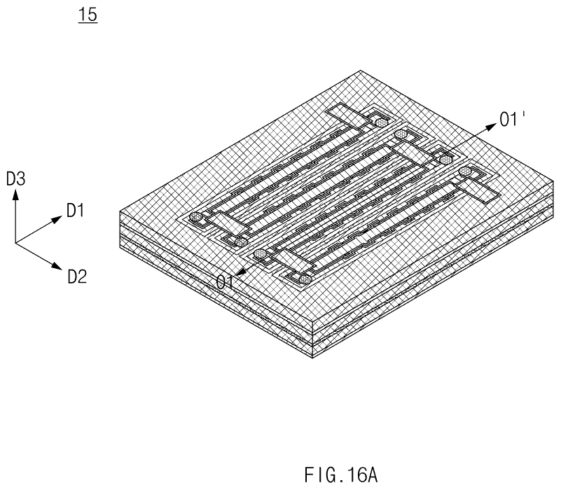

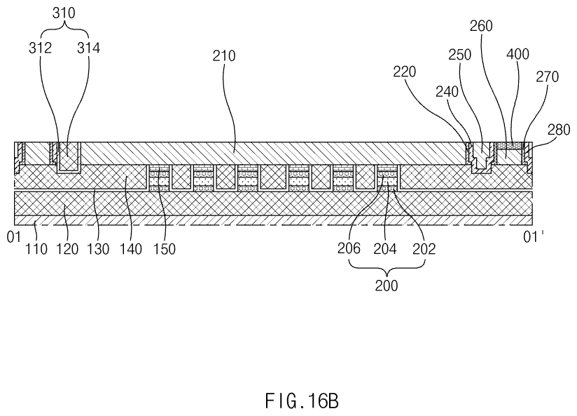

FIG. 16A is a sectional perspective view 14 of the semiconductor device for describing the position of the contact plug 400.

FIG. 16B is a sectional view taken along line O1-O1′ of FIG. 16A.

Referring to FIG. 16B, the contact plug 400 may be formed in a region in contact with the island gate 260.

The contact plug 400 may commonly overlap with the island gate 260 and the second gate 250. Accordingly, the island gate 260 and the second gate 250 may be electrically connected by the contact plug 400.

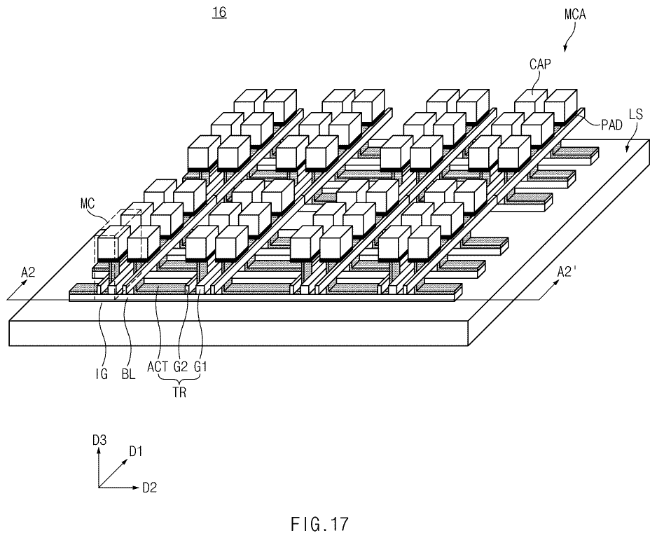

FIG. 17 is a schematic perspective view of a semiconductor device 16 according to an embodiment of the present disclosure.

The structure of the semiconductor device 16 will be described with reference to FIG. 17.

The semiconductor device 16 may include a substrate LS and a plurality of memory cells formed over the substrate LS and repeatedly arranged. Each of the memory cells may have a three-dimensional structure.

Referring to FIG. 17, the semiconductor device 16 may include the substrate LS and may include a memory cell array MCA formed over the substrate LS. The memory cell array MCA may include a plurality of memory cells MC repeatedly arranged on the substrate LS.

According to an embodiment, each of the memory cells MC may have a three-dimensional structure.

For example, each of the memory cells MC included in the memory cell array MCA may include a bit line BL, a transistor TR, a contact pad PAD, and a capacitor CAP.

The transistor TR may include a first gate G1, a second gate G2, and an active region ACT disposed between the first gate G1 and the second gate G2.

Unlike in the embodiment of FIG. 1, the semiconductor device 16 of FIG. 17 may not include the island gate IG.

Except for the shapes of the island gate IG, the first gate G1, and the second gate G2, the structure of the semiconductor device 16 is substantially the same as the structure of the semiconductor device 1 of FIG. 1, and therefore repetitive description will be omitted.

The first gate G1 and the second gate G2 included in each of the memory cells MC may be connected with an external control circuit through a contact plug.

The contact plug may be a vertical via extending from a conductive line included in the control circuits to the first gate G1, the second gate G2, or the bit line BL. The contact plug may include a conductive material such as metal or silicon, and a control signal may be provided to the first gate G1, the second gate G2, or the bit line BL through the contact plug.

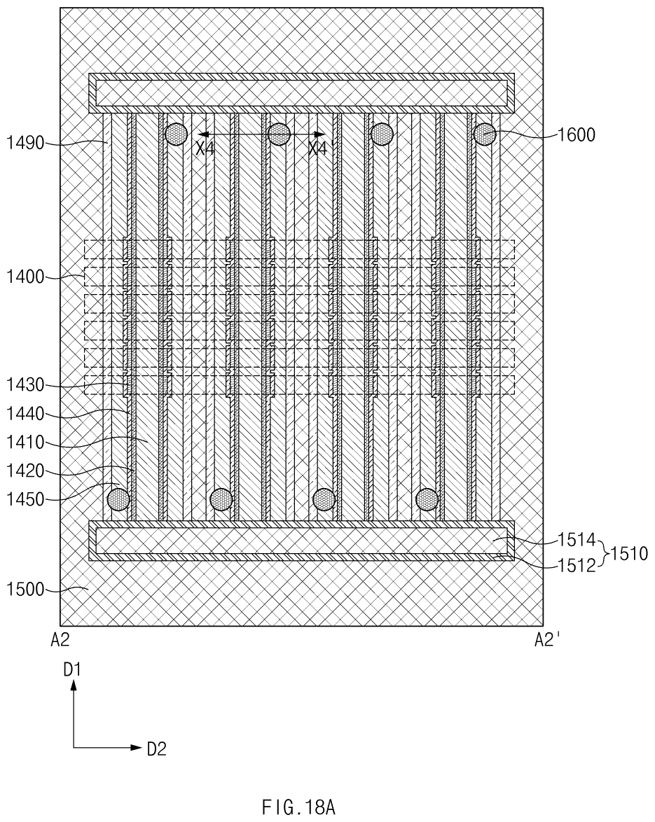

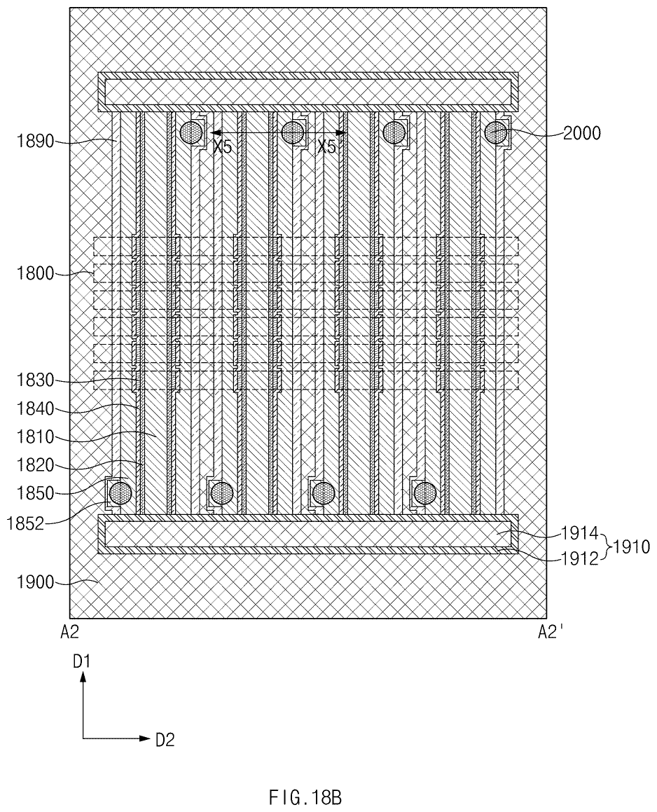

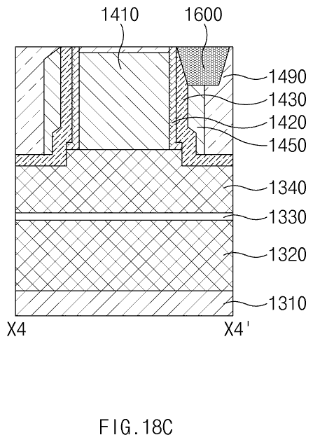

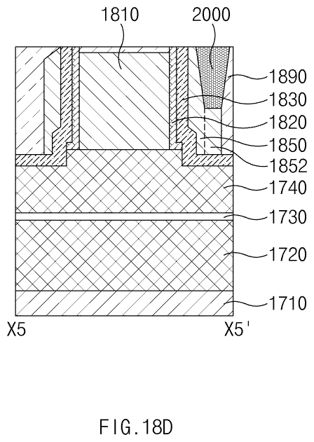

FIG. 18A is a sectional view of the semiconductor device according to an embodiment of the present disclosure. FIG. 18B is a sectional view of the semiconductor device according to an embodiment of the present disclosure.

In FIGS. 18A and 18B, the semiconductor device is illustrated as including six bit lines 1400 or 1800, four first gates 1410, or 1810, and eight second gates 1450, or 1850. However, this is merely illustrative, and the semiconductor device may actually include more bit lines and gates.

In addition, the cross-sections illustrated in FIGS. 18A and 18B may be exaggerated or modified for convenience of description.

Each of FIGS. 18A and 18B is a sectional view of the semiconductor device 16 taken along line A2-A2′ of FIG. 17. Line A2-A2′ may be a line that cuts at least portions of the first gates 1410 or 1810 and the second gates 1450 or 1850 so as to disclose the positional relationship between the first gates 1410 or 1810 and the second gates 1450 or 1850.

Referring to the sectional view of FIG. 18A, the semiconductor device 16 may include the bit line 1400 disposed in the substrate. The semiconductor device may include the first gate 1410, a first gate insulating layer 1420 in contact with the first gate 1410, an active region 1430 in contact with the first gate insulating layer 1420, a second gate insulating layer 1440 in contact with the active region 1430, and the second gate 1450 in contact with the second gate insulating layer 1440.

In addition, the semiconductor device 16 may include a gate spacer 1490 in contact with the second gate 1450 and disposed between the adjacent second gates 1450. The semiconductor device 16 may include a second interlayer insulating layer 1500 surrounding the gate spacer 1490.

Separation regions 1510 may be disposed at the opposite ends of the first gate 1410 and the second gate 1450 that extend in the first direction (e.g., the direction D1).

A contact plug 1600 may be connected to each second gate 1450.

The cross-section of the semiconductor device according to the embodiment of FIG. 18A is substantially the same as the cross-section of the semiconductor device described with reference to FIGS. 2A, 2B, and 2C except for the shape of the separation regions 1510 and the shape of the contact plug 1600, and therefore repetitive description will be omitted.

The separation regions 1510 may be disposed at the opposite ends of the first gate 1410 with any first gate 1410 therebetween. More specifically, as illustrated in FIG. 18A In addition, the separation regions 1510 may be disposed at the opposite ends of the second gate 1450 with any second gate 1450 therebetween. More specifically, as illustrated in FIG. 18A, the separation regions 1510 may be positioned at the opposite ends of the first and second gates 1410, and 1450 and may include a second separation layer 1514 extending in the second direction D2 and a first separation layer 1512 surrounding the second separation layer 1514. The first separation layer 1512 of the separation regions 1510 may contact the opposite ends of the first and second gates 1410 and 1450.

Since the separation region 1510 is formed, two adjacent second gates 1450 may be separated from each other, and each second gate 1450 may operate as an individual word line.

Different word line control signals may be provided through the contact plugs 1600 connected to the second gates 1450 separated by the separation region 1510.

The separation region 1510 may include a first separation layer 1512 and a second separation layer 1514. For example, the first separation layer 1512 may include silicon nitride, and the second separation layer 1514 may include silicon oxide.

The contact plug 1600 may be disposed to overlap one second gate 1450.

According to the embodiment of FIG. 18A, the contact plug 1600 may have a diameter narrower than the width of the second gate 1450.

The contact plug 1600 may extend in a direction perpendicular to the first direction (e.g., the direction D1) and the second direction (e.g., the direction D2).

Referring to the sectional view of FIG. 18B, the semiconductor device 16 may include the bit line 1800 disposed in the substrate. The semiconductor device may include the first gate 1810, a first gate insulating layer 1820 in contact with the first gate 1810, an active region 1830 in contact with the first gate insulating layer 1820, a second gate insulating layer 1840 in contact with the active region 1830, and the second gate 1850 in contact with the second gate insulating layer 1840.

In addition, the semiconductor device 16 may include a gate spacer 1890 in contact with the second gate 1850 and disposed between the adjacent second gates 1850 and may include a second interlayer insulating layer 1900 surrounding the gate spacer 1890.

Separation regions 1910 may be disposed at the opposite ends of the first gate 1810 and the second gate 1850 that extend in the first direction (e.g., the direction D1).

A contact plug 2000 may be connected to each second gate 1850.

The cross-section of the semiconductor device according to the embodiment of FIG. 18B is substantially the same as the cross-section of the semiconductor device described with reference to FIG. 18A except for the shape of the second gate 1850 and the shape of the contact plug 1600, and therefore repetitive description will be omitted.

The second gate 1850 of FIG. 18b may include an extension region 1852. The extension region 1852 may be a region formed through an additional etching process and may include the same material as the second gate 1850. For example, the extension region 1852 may include a conductive material.

The extension region 1852 may be a region extending in the second direction (e.g., the direction D2) from the center of the second gate 1850. As the extension region 1852 is formed, a region where the contact plug 2000 is disposed may be additionally secured.

FIG. 18C is a sectional view of the semiconductor device taken along cutting line X4-X4′ of FIG. 18A.

Cutting line X4-X4′ may be a cutting line that extends along the center of the contact plug 1600 and passes through the first gate 1410.

Referring to FIG. 18C, a first interlayer insulating layer 1320 may be disposed over a substrate layer 1310, and a first bit line insulating layer 1330 may be disposed over the first interlayer insulating layer 1320. In addition, a second bit line insulating layer 1340 may be disposed over the first bit line insulating layer 1330, and the first gate 1410 may be disposed over the second bit line insulating layer 1340.

The first gate insulating layer 1420 and the second gate insulating layer 1430 may be disposed along the side surface of the first gate 1410, and the second gate 1450 may be disposed along the sidewall of the second gate insulating layer 1430.

The second gate 1450 may be surrounded by the gate spacer 1490.

The contact plug 1600 may contact the second gate 1450.

In the embodiment of FIG. 18C, the contact plug 1600 is formed to contact only the second gate 1450 and not in contact with the first gate 1410. As a result, the region where the contact plug 1600 can be formed is limited. For example, the contact plug 1600 may be formed in a region obtained by removing at least portions of the second gate insulating layer 1430, the second gate 1450, and the gate spacer 1490. The contact plug 1600 may include a conductive material.

FIG. 18D is a sectional view of the semiconductor device taken along cutting line X5-X5′ of FIG. 18B.

Cutting line X5-X5′ may be a cutting line that extends along the center of the contact plug 2000 and passes through the first gate 1810.

Referring to FIG. 18D, a first interlayer insulating layer 1720 may be disposed over a substrate layer 1710, and a first bit line insulating layer 1730 may be disposed over the first interlayer insulating layer 1720. In addition, a second bit line insulating layer 1740 may be disposed over the first bit line insulating layer 1730, and the first gate 1810 may be disposed over the second bit line insulating layer 1740.

The first gate insulating layer 1820 and the second gate insulating layer 1830 may be disposed along the side surface of the first gate 1810, and the second gate 1850 may be disposed along the sidewall of the second gate insulating layer 1830.

The second gate 1850 may be surrounded by the gate spacer 1890.

The contact plug 2000 may contact the second gate 1850.

In the embodiment of FIG. 18D, the second gate 1850 may include the extension region 1852.

The extension region 1852 may be a region extending along the sidewall of the second gate 1850 and may include a conductive material.

As the extension region 1852 is formed, a region where the contact plug 2000 is disposed may be additionally secured.

For example, the contact plug 2000 may be formed on the second gate 1850 including the extension region 1852. The contact plug 2000 may include a conductive material.

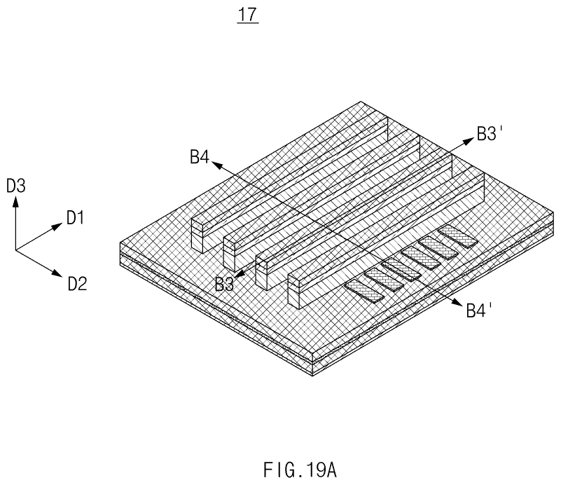

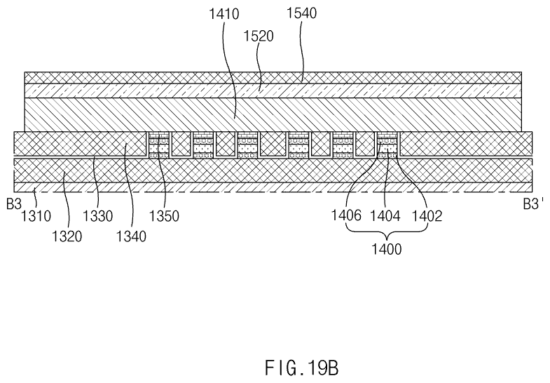

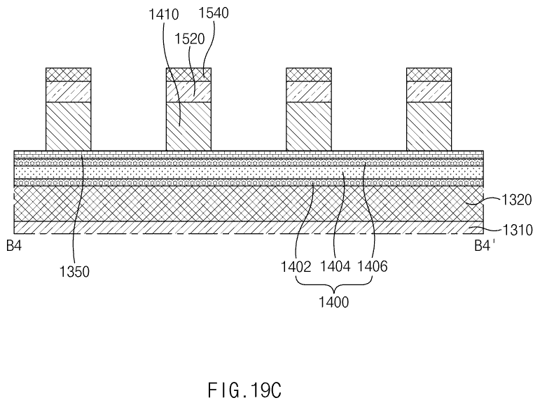

FIGS. 19A to 31A, FIGS. 19B to 31B, and FIGS. 19C to 31C are views for describing fabrication operations of the semiconductor device according to an embodiment of the present disclosure.

FIG. 19A is a perspective view 17 illustrating a fabrication operation of the semiconductor device for forming the first gate 1410 on the bit line.

In the perspective view 17, a shape in which the first gates are disposed over the plurality of bit lines extending in the second direction (e.g., the direction D2) is illustrated.

FIG. 19B is a sectional view taken along line B3-B3′ of FIG. 19A, and FIG. 19C is a sectional view taken along line B4-B4′ of FIG. 19A.

FIG. 19B is a sectional view illustrating a cross-section of the first gate 1410 in the first direction (e.g., the direction D1).

FIG. 19C is a sectional view illustrating cross-sections of the plurality of first gates 1410 disposed in the second direction (e.g., the direction D2).

Referring to FIGS. 19B and 19C, the first interlayer insulating layer 1320 may be disposed over the substrate layer 1310, and the bit line 1400 may be disposed over the first interlayer insulating layer 1320.

The bit line 1400 may include a plurality of layers. For example, the bit line 1400 of FIG. 19B may include a first bit line layer 1402, a second bit line layer 1404, and a third bit line layer 1406. According to an embodiment, the first bit line layer 1402 and the third bit line layer 1406 may include titanium nitride (TiN), and the second bit line layer 1404 may include tungsten (W).

The bit line 1400 may be formed through an etching process using a mask after the plurality of layers are deposited.

The bit lines 1400 may be electrically isolated from each other by a plurality of layers. For example, the first bit line insulating layer 1330 may be disposed along the sidewalls of the bit lines 1400, and the second bit line insulating layer 1340 may be disposed between the bit lines 1400.

The first bit line insulating layer 1330 may include, for example, silicon nitride, and the second bit line insulating layer 1340 may include silicon oxide.

The first bit line insulating layer 1330 and the second bit line insulating layer 1340 may separate the adjacent bit lines 1400 from each other.

A third bit line insulating layer 1350 may be disposed over each of the bit lines 1400. The third bit line insulating layer 1350 may include an insulating material.

The third bit line insulating layer 1350 may include, for example, silicon oxide, silicon nitride, silicon carbonate, metal oxide, metal oxy nitride, metal silicate, a high-k material, a ferroelectric material, an anti-ferroelectric material, or a combination thereof.

The first gate 1410 and the bit line 1400 may be electrically isolated from each other by the third bit line insulating layers 1350.

The first gate 1410 may include a metal, a metal mixture, a metal alloy, titanium nitride, tungsten, poly silicon, or a combination thereof. For example, the first gate 1410 may include titanium nitride.

The first gate 1410 may be disposed to at least partially overlap with the bit line 1400. The first gate 1410 may be formed by sequentially forming a titanium nitride layer, a silicon nitride layer, and a silicon oxide layer over the bit line 1400 and etching the layers using a mask including a spin on carbon (Soc) layer and a SiON layer.

According to an embodiment, a separate island gate other than the first gate 1410 may not be formed.

A first gate upper insulating layer 1520 and a first gate upper protection layer 1540 formed over the first gate 1410 may prevent damage to the first gate 1410 during the semiconductor device fabrication process.

The first gate upper insulating layer 1520 may electrically isolate the first gate 1410 from other components (e.g., the active region) included in the semiconductor device.

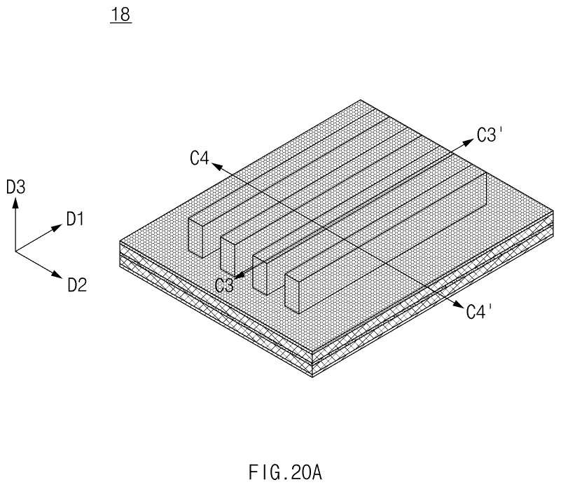

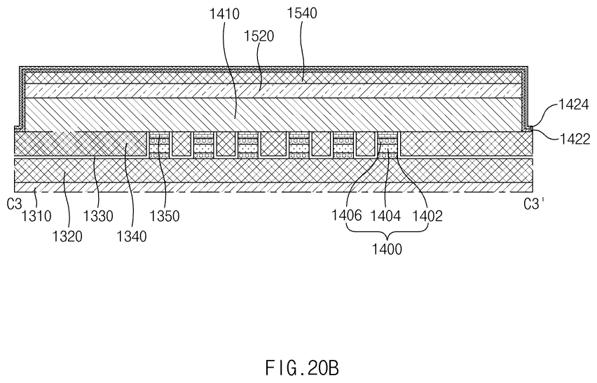

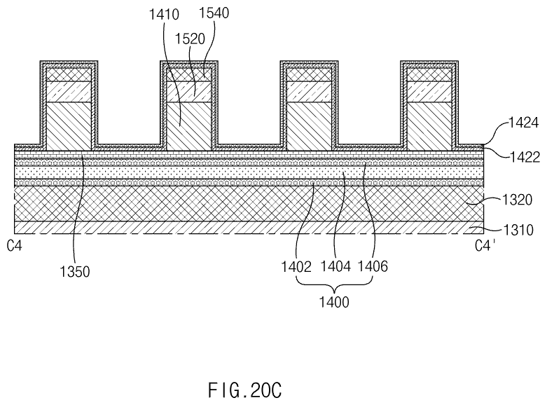

FIG. 20A is a perspective view 18 illustrating a fabrication operation of the semiconductor device for forming a first pre-gate insulating layer and an insulating film protection layer over the first gate 1410.

In the perspective view 18, a shape in which a plurality of layers are disposed over the first gate 1410 is illustrated.

FIG. 20B is a sectional view taken along line C3-C3′ of FIG. 20A, and FIG. 20C is a sectional view taken along line C4-C4′ of FIG. 20A.

Referring to FIGS. 20B and 20C, the first pre-gate insulating layer 1422 and the insulating film protection layer 1424 may be formed over the first gate 1410 and the third bit line insulating layer 1350.

The first pre-gate insulating layer 1422 may include silicon oxide. The insulating film protection layer 1424 may include poly silicon.

By forming the insulating film protection layer 1424, the first gate insulating layer 1420 formed from the first pre-gate insulating layer 1422 during the fabrication process of the active region 1430 in contact with the bit line 1400 may be protected.

By placing the insulating film protection layer 1424, damage to the first gate insulating layer 1420 during a plasma etching process may be prevented. The insulating film protection layer 1424 serves as a physical shield, mitigating the impact of high-energy plasma ions that may otherwise erode the gate insulator. For example, it helps prevent a reduction in the thickness of the first gate insulating layer 1420 and protects against the formation of surface defects such as roughness or voids, both of which could compromise device reliability and electrical performance.

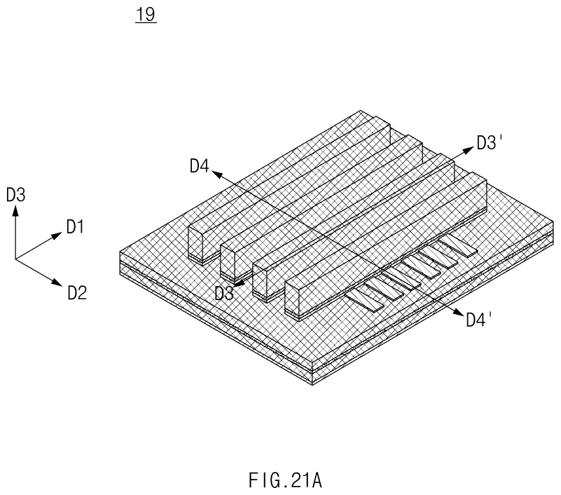

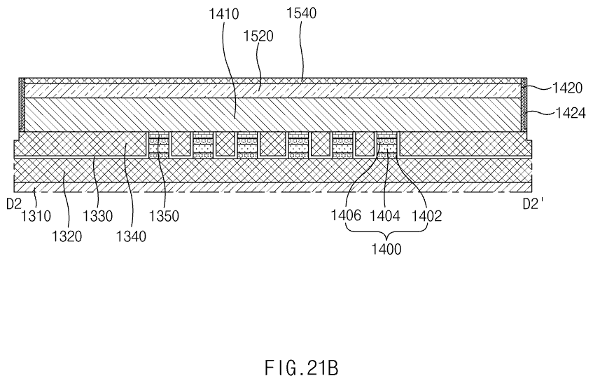

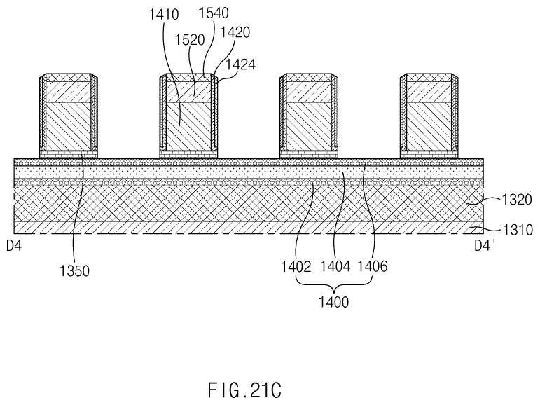

FIG. 21A is a perspective view 19 illustrating a fabrication operation of the semiconductor device for forming the first gate insulating layer 1420 by etching the first gate 1410 and the first pre-gate insulating layer 1422.

In the perspective view 19, a shape in which the first gate insulating layer 1420 is formed and at least a portion of the insulating film protection layer 1424 is removed is illustrated.

FIG. 21B is a sectional view taken along line D3-D3′ of FIG. 21A, and FIG. 21C is a sectional view taken along line D4-D4′ of FIG. 21A.

Referring to FIGS. 21B and 21C, a portion of the first pre-gate insulating layer 1422 may be removed, and the first gate insulating layer 1420 may be formed.

Since at least a portion of the first pre-gate insulating layer 1422 is removed through plasma etching, the first pre-gate insulating layer 1422 may be the first gate insulating layer 1420.

Due to the etching process, a portion of the second bit line insulating layer 1340 may be removed, and at least a portion of the third bit line insulating layer 1350 disposed over the bit line 1400 between the first gates 1410 may be removed to expose the bit line 1400.

After the etching process, the insulating film protection layer 1424 overlapping the first gate insulating layer 1420 may be selectively left.

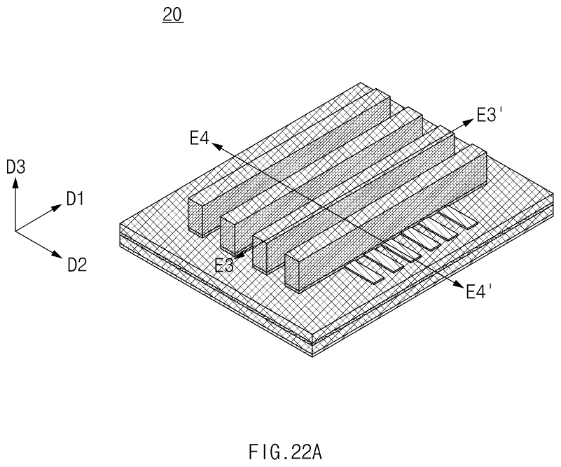

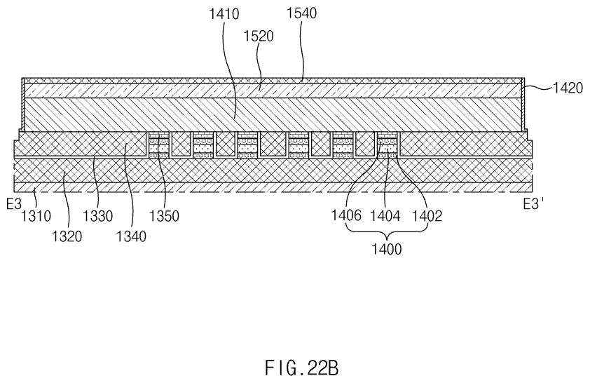

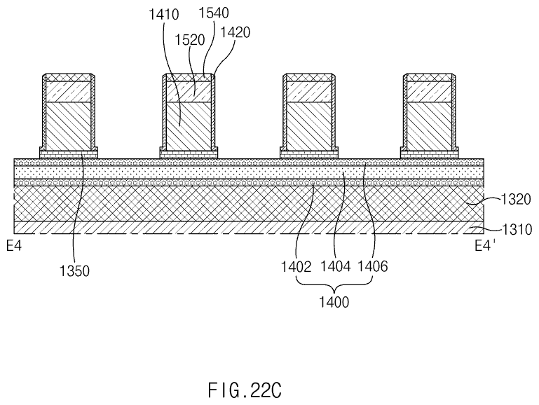

FIG. 22A is a perspective view 20 illustrating a fabrication operation of the semiconductor device for removing the insulating film protection layer 1424.

In the perspective view 20, a shape in which the insulating film protection layer 1424 that protects the first gate insulating layer 1420 during the etching process is removed is illustrated.

FIG. 22B is a sectional view taken along line E3-E3′ of FIG. 22A, and FIG. 22C is a sectional view taken along line E4-E4′ of FIG. 22A.

Referring to FIGS. 22B and 22C, the selectively left insulating film protection layer 1424 may be removed. Since the insulating film protection layer 1424 is removed, the first gate insulating layer 1420 may be exposed to the outside.

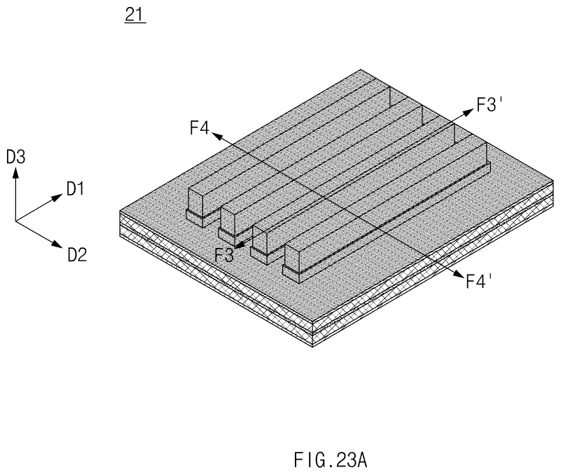

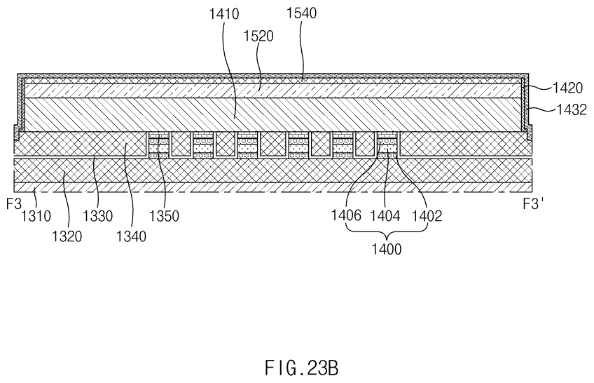

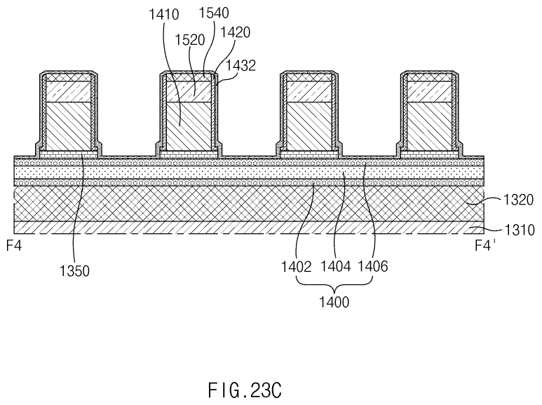

FIG. 23A is a perspective view 21 illustrating a fabrication operation of the semiconductor device for forming an oxide semiconductor layer 1432 over the bit line 1400 and the first gate insulating layer 1420.

FIG. 23B is a sectional view taken along line F3-F3′ of FIG. 23A, and FIG. 23C is a sectional view taken along line F4-F4′ of FIG. 23A.

Referring to FIGS. 23B and 23C, the oxide semiconductor layer 1432 may be formed over the bit line 1400 and the first gate insulating layer 1420. In particular, the bit line 1400 may be electrically connected with the oxide semiconductor layer 1432.

For example, the oxide semiconductor layer 1432 may include a material such as IGZO and may be formed by an atomic layer deposition method.

When the oxide semiconductor layer 1432 is formed by the atomic layer deposition method, the thickness may be easily adjusted, and the film quality may be uniformly formed. Thus, the electrical characteristics of the semiconductor device may be improved.

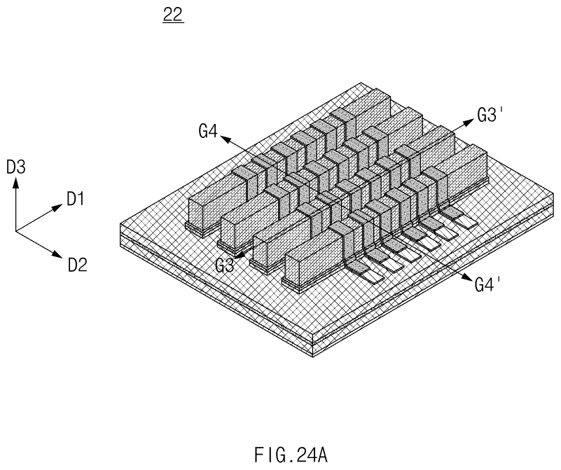

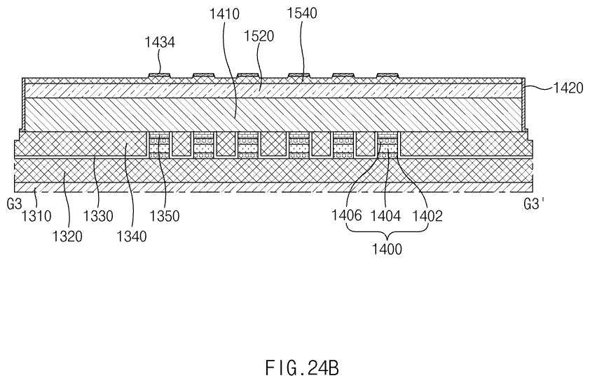

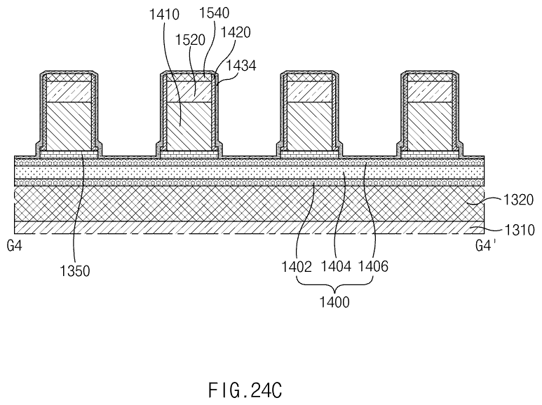

FIG. 24A is a perspective view 22 illustrating a fabrication operation of the semiconductor device for forming a pre-active region 1434 by removing at least a portion of the oxide semiconductor layer 1432.

FIG. 24B is a sectional view taken along line G3-G3′ of FIG. 24A, and FIG. 24C is a sectional view taken along line G4-G4′ of FIG. 24A.

Referring to FIGS. 24B and 24C, the oxide semiconductor layer 1432 may be separated into a plurality of pre-active regions 1434 in the first direction (e.g., the direction D1).

For example, each of the plurality of pre-active regions 1434 formed from the oxide semiconductor layer 1432 may be electrically connected to the bit line 1400.

According to an embodiment, a mask including a spin on carbon (SOC) layer and a SiON layer may be formed over the oxide semiconductor layer 1432, and the pre-active regions 1434 may be selectively formed by selectively etching the oxide semiconductor layer 1432.

The oxide semiconductor layer 1432 in the region where the pre-active region 1434 is not formed may be removed. For example, the oxide semiconductor layer 1432 disposed over the sidewall of the first gate 210 may be removed through etching.

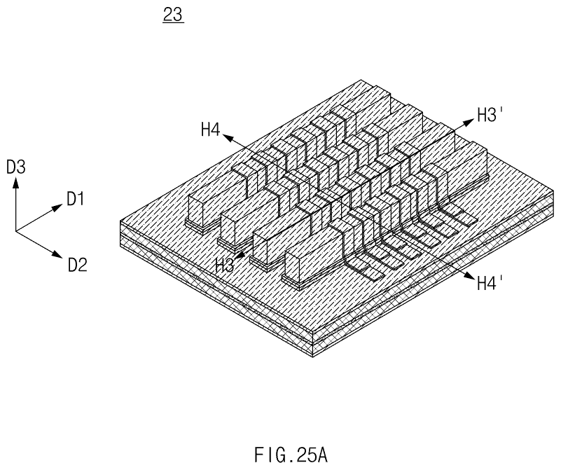

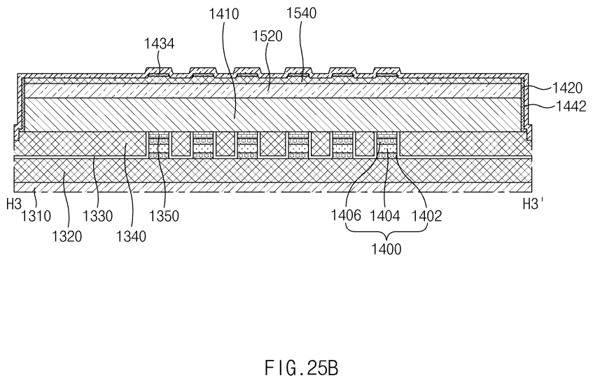

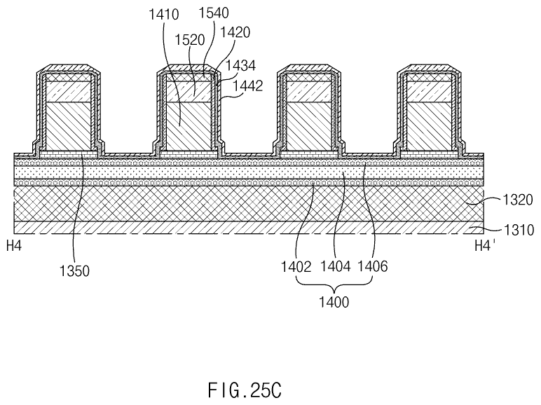

FIG. 25A is a perspective view 23 illustrating a fabrication operation of the semiconductor device for forming a second pre-gate insulating layer 1442 over the pre-active region 1434.

FIG. 25B is a sectional view taken along line H3-H3′ of FIG. 25A, and FIG. 25C is a sectional view taken along line H4-H4′ of FIG. 25A.

Referring to FIGS. 25B and 25C, the second pre-gate insulating layer 1442 may be formed over the plurality of pre-active regions 1434. The second pre-gate insulating layer 1442 may include an insulating layer of silicon oxide. The second pre-gate insulating layer 1442 serves to electrically isolate the pre-active region 1434 from the second gate 1450.

The second pre-gate insulating layer 1442 may be formed to cover the sidewall and the upper portion of the first gate 1410.

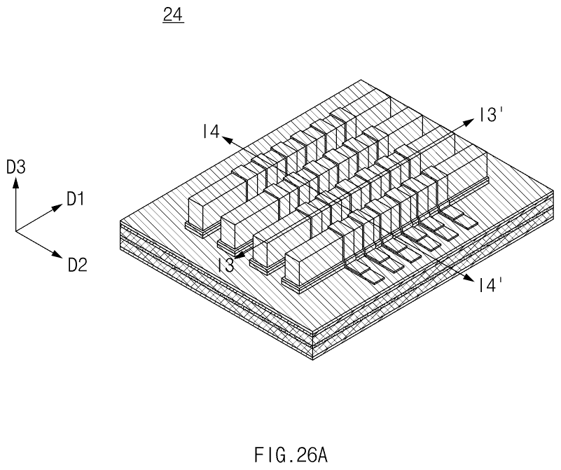

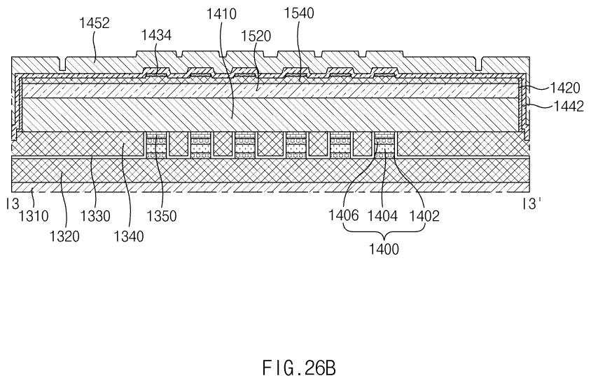

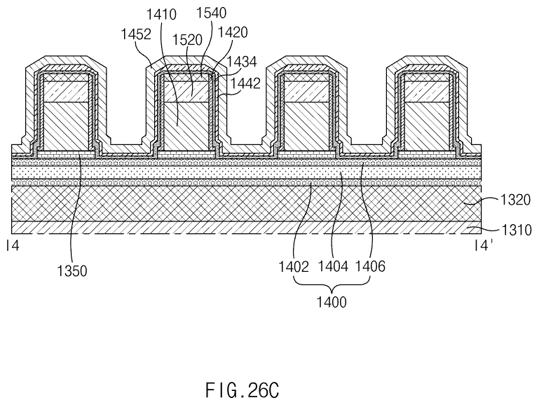

FIG. 26A is a perspective view 24 illustrating a fabrication operation of the semiconductor device for forming a conductive material layer 1452 over the second pre-gate insulating layer 1442.

FIG. 26B is a sectional view taken along line I3-I3′ of FIG. 26A, and FIG. 26C is a sectional view taken along line I4-I4′ of FIG. 26A.

Referring to FIGS. 26B and 26C, the conductive material layer 1452 may be formed over the second pre-gate insulating layer 1442. The conductive material layer 1452 may include a conductive material such as titanium nitride.

The conductive material layer 1452 may be formed to surround the sidewall and the upper portion of the first gate 1410.

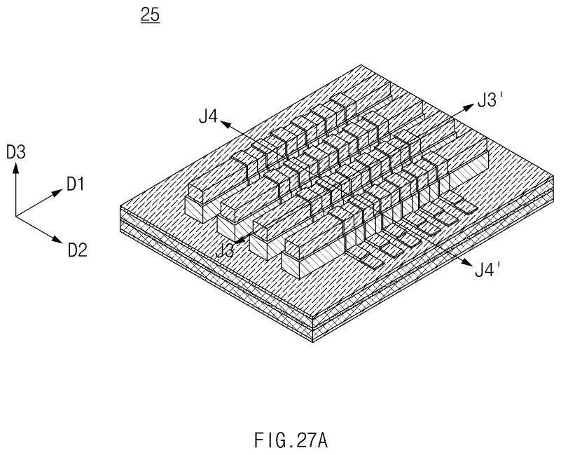

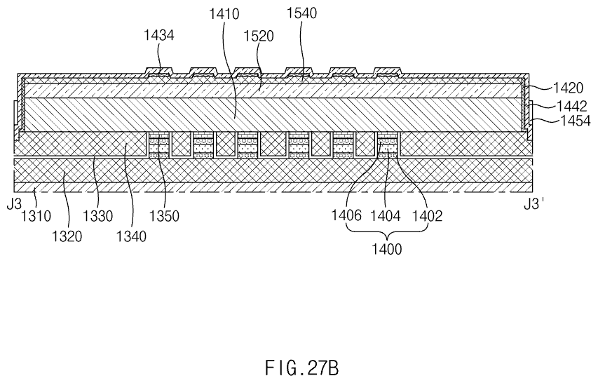

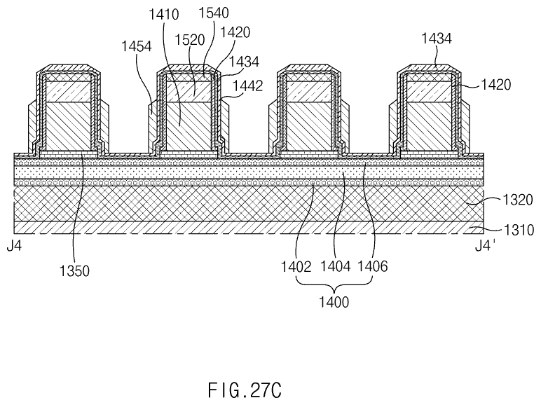

FIG. 27A is a perspective view 25 illustrating a fabrication operation of the semiconductor device for forming a second pre-gate 1454 by etching at least a portion of the conductive material layer 1452.

FIG. 27B is a sectional view taken along line J3-J3′ of FIG. 27A, and FIG. 27C is a sectional view taken along line J4-J4′ of FIG. 27A.

Referring to FIGS. 27B and 27C, the second pre-gate 1454 may be formed by selectively etching the conductive material layer 1452.

The second pre-gate 1454 may be formed by selectively etching the conductive material layer 1452 disposed over the first gate 1410.

According to an embodiment, the second pre-gate 1454 may be formed to have the same height as the first gate 1410.

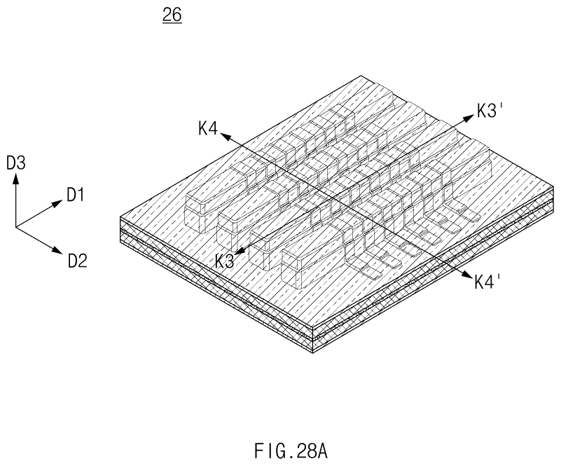

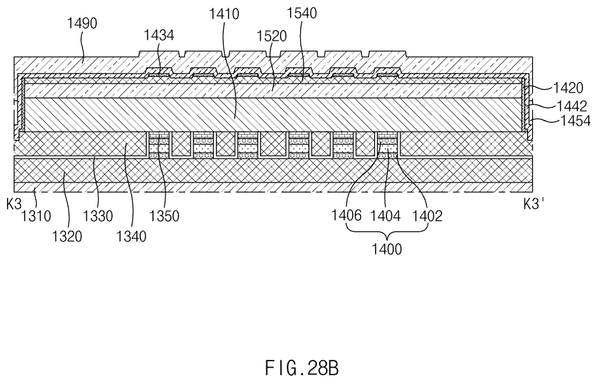

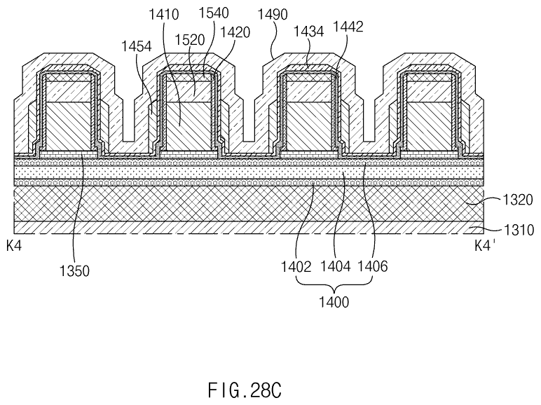

FIG. 28A is a perspective view 26 illustrating a fabrication operation of the semiconductor device for forming the gate spacer 1490 over the second pre-gate 1454 and the second pre-gate insulating layer 1442.

FIG. 28B is a sectional view taken along line K3-K3′ of FIG. 28A, and FIG. 28C is a sectional view taken along line K4-K4′ of FIG. 28A.

Referring to FIGS. 28B and 28C, the gate spacer 1490 may be formed over the second pre-gate 1454.

According to an embodiment, the gate spacer 1490 may include silicon nitride. The gate spacer 1490 may electrically isolate the second pre-gate 1454 from other components included in the semiconductor device. For example, the gate spacer 1490 may electrically isolate the adjacent second pre-gate 1454.

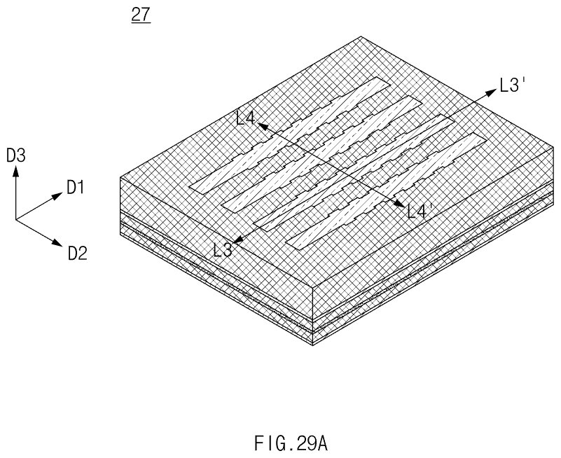

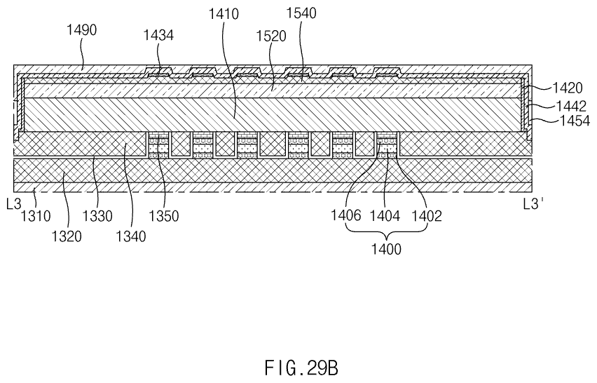

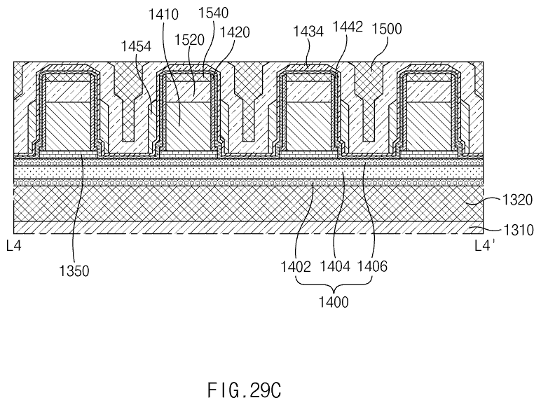

FIG. 29A is a perspective view 27 illustrating a fabrication operation of the semiconductor device for forming the second interlayer insulating layer 1500 between the gate spacers 1490 and removing a portion of the gate spacer 1490 and a portion of the second interlayer insulating layer 1500.

FIG. 29B is a sectional view taken along line L3-L3′ of FIG. 29A, and FIG. 29C is a sectional view taken along line L4-L4′ of FIG. 29A.

Referring to FIGS. 29B and 29C, the second interlayer insulating layer 1500 may be formed between the gate spacers 1490.

According to an embodiment, the second interlayer insulating layer 1500 may include silicon oxide.

The gate spacer 1490 and the second interlayer insulating layer 1500 may be at least partially removed through a chemical mechanical polishing (CMP) process.

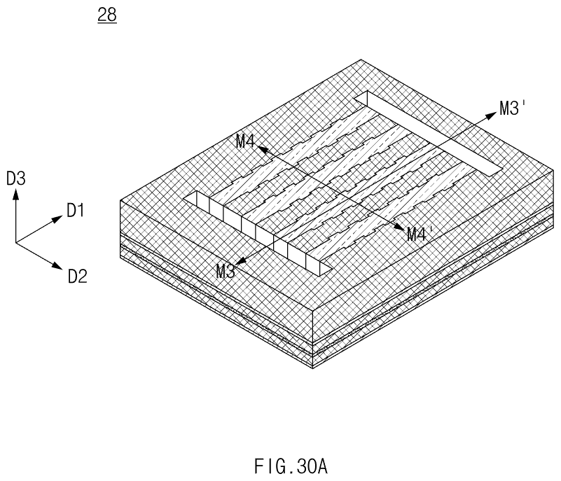

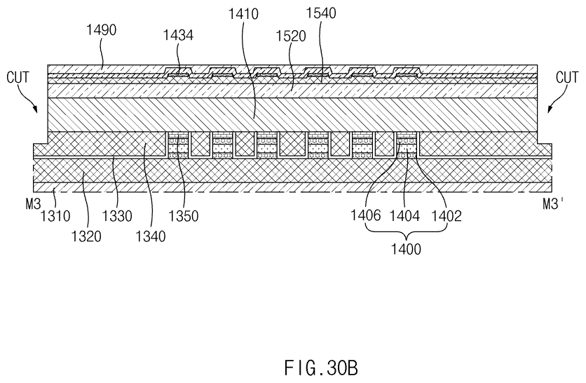

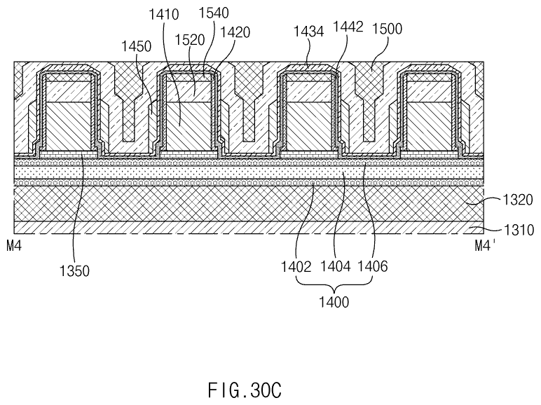

FIG. 30A is a perspective view 28 illustrating a fabrication operation of the semiconductor device for etching a portion of the second pre-gate 1454, a portion of the first gate insulating layer 1420, and a portion of the second pre-gate insulating layer 1442 to form the second gate 1450 and forming a cut region CUT.

FIG. 30B is a sectional view taken along line M3-M3′ of FIG. 30A, and FIG. 30C is a sectional view taken along line M4-M4′ of FIG. 30A.

Referring to FIGS. 30B and 30C, the cut region CUT may be formed at the opposite ends of the first gate 1410.

The cut region CUT may be formed through an etching process. By forming the cut region CUT, the second pre-gate 1454 formed over the sidewall of the first gate 1410 may be separated into two second gates 1450.

According to an embodiment, the cut region CUT may etch a portion of the first gate 1410 and a portion of the second pre-gate 1452. The cut region CUT may be formed through selective etching using a mask. As illustrated in FIG. 30A, the cut region CUT may be formed at the opposite ends of the first gates 1410 and the second pre-gates 1454.

Portions of the first gate insulating layer 1420 disposed at the opposite ends of the first gate 1410 may be removed by the cut region CUT.

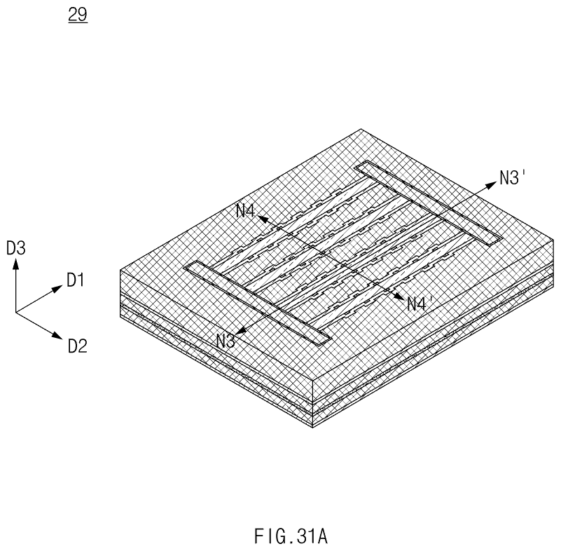

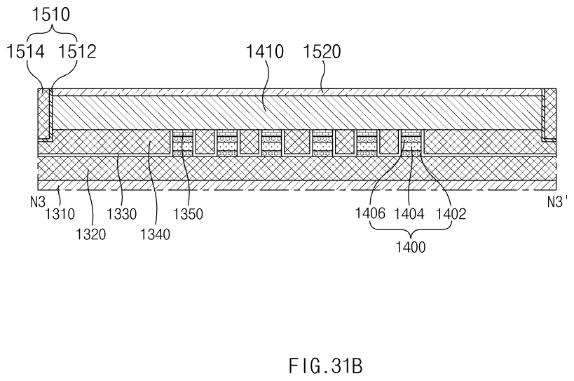

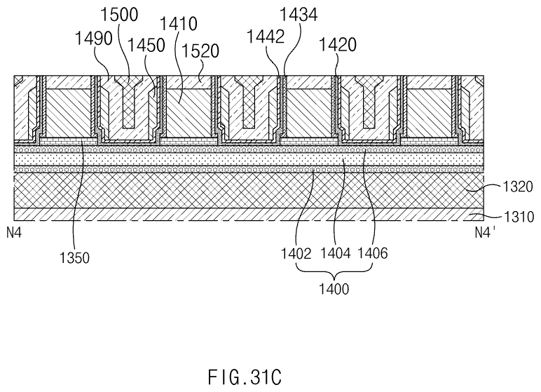

FIG. 31A is a perspective view 29 illustrating a fabrication operation of the semiconductor device for forming the separation region 1510 in the cut region CUT.

FIG. 31B is a sectional view taken along line N3-N3′ of FIG. 31A, and FIG. 31C is a sectional view taken along line N4-N4′ of FIG. 31A.

Referring to FIGS. 31B and 31C, the first separation layer 1512 and the second separation layer 1514 may be formed in the cut region CUT.

In an embodiment, the first separation layer 1512 may include silicon nitride, and the second separation layer 1514 may include silicon oxide.

The first separation layer 1512 and the second separation layer 1514 may be formed through deposition and etching.

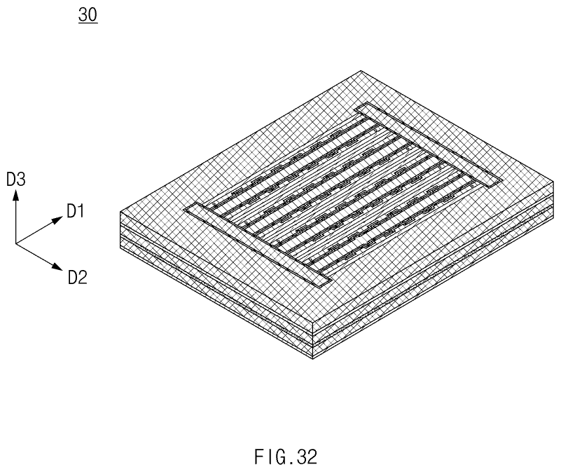

FIG. 32 is a sectional perspective view 30 of the semiconductor device for describing the position of the contact plug (1600 of FIG. 18A).

Referring to FIG. 32 and FIG. 18A, the contact plug (1600 of FIG. 18A) may be disposed to overlap with the second gate (1450 of FIG. 18A). The contact plug (1600 of FIG. 18A) may be disposed to overlap one end of any second gate (1450 of FIG. 18A).

As described above, the semiconductor device of the present disclosure may include the active region having a three-dimensional shape. Thus, the semiconductor device with improved integration may be provided.

The semiconductor device of the present disclosure may include the island gate connected to the contact plug, thereby improving the contact stability between the contact plug and the gate and simplifying the fabrication process.

In addition, the disclosure may provide various advantageous effects that are directly or indirectly recognized by one of ordinary skill in the art.

Hereinabove, although the embodiments of the present disclosure have been described with reference to specific embodiments and the accompanying drawings, the embodiments are not limited thereto, but may be variously modified and altered by those skilled in the art to which the present disclosure pertains without departing from the scope of the present disclosure.

What is claimed is:

1. A semiconductor device comprising:
a first gate configured to extend in a first direction;
an island gate adjacent to one end of the first gate in the first direction;
a second gate spaced apart from the first gate in a second direction perpendicular to the first direction and configured to extend in the first direction; and
a contact plug in contact with the island gate and the second gate.

2. The semiconductor device of claim 1, wherein the island gate has a quadrangular shape.

3. The semiconductor device of claim 2, wherein the second gate surrounds at least three sides of the island gate.

4. The semiconductor device of claim 1, wherein the second gate includes a bridge portion disposed between the island gate and the first gate.

5. The semiconductor device of claim 1, wherein the second gate contacts the island gate.

6. The semiconductor device of claim 1, further comprising:
a bit line spaced apart from the first gate in a third direction perpendicular to the first direction and the second direction and configured to extend in the second direction.

7. The semiconductor device of claim 6, further comprising:
an active region in contact with the bit line,
wherein the active region includes a horizontal portion in contact with the bit line and configured to extend in the second direction and a vertical portion configured to extend in the third direction.

8. The semiconductor device of claim 7, wherein the vertical portion is disposed between the first gate and the second gate.

9. The semiconductor device of claim 8, wherein the first gate is disposed between the vertical portions included in the adjacent active regions, respectively.

10. The semiconductor device of claim 8, wherein the active region includes an oxide semiconductor.

11. The semiconductor device of claim 1, further comprising:
a separation region configured to separate adjacent second gates from each other.

12. The semiconductor device of claim 11, wherein the separation region is disposed between the first gate and the island gate.

13. The semiconductor device of claim 11, wherein the separation region contacts one end of the second gate in the first direction.

14. The semiconductor device of claim 1, wherein a voltage provided to the first gate is different from a voltage provided to the second gate.

15. The semiconductor device of claim 14, wherein the voltage provided to the first gate is a ground voltage.

16. The semiconductor device of claim 1, further comprising:
another island gate adjacent to an opposite end of the first gate in the first direction; and
another contact plug electrically connected to the another island gate.

17. The semiconductor device of claim 16, wherein the contact plug and the another contact plug are disposed in a diagonal direction with respect to the center of the first gate.

18. A semiconductor device comprising:
a first gate configured to extend in a first direction;
a bit line configured to extend in a second direction perpendicular to the first direction;
a second gate spaced apart from the first gate in the second direction;
an active region including a horizontal portion in contact with the bit line and a vertical portion configured to extend in a third direction perpendicular to the first direction and the second direction;
an island gate adjacent to one end of the first gate in the first direction; and
a contact plug configured to overlap with the island gate and the second gate,
wherein the vertical portion is disposed between the first gate and the second gate.

19. The semiconductor device of claim 18, further comprising:
a separation region configured to separate adjacent second gates from each other.

20. A semiconductor device comprising:
a first gate and a second gate extending in a first direction and spaced apart from each other in a second direction that is perpendicular to the first direction; and
an island gate adjacent to a first end of the first gate;
wherein the second gate surrounds three sides of the island gate, and
wherein the second gate includes a bridge portion disposed between the island gate and the first gate.
